(19) United States
(12) Patent Application Publication
(10) Pub. No.: US 2025/0231490 A1
(43) Pub. Date: Jul. 17, 2025

(54) WAFER HOLDER APPARATUS, SYSTEM AND METHOD OF FORMING SAME

(71) Applicant: Taiwan Semiconductor Manufacturing Company, LTD., Hsinchu (TW)

(72) Inventors: Heng-Wei Liao, Taichung (TW); De-Fang Huang, Hsinchu (TW); Chih Yang Lee, Hsinchu (TW); Ching-Feng Chiu, New Taipei (TW)

(21) Appl. No.: 18/409,950

(22) Filed: Jan. 11, 2024

(51) Int. Cl. G03F 7/16; G03F 7/00; H01L 21/67

(52) U.S. Cl. CPC G03F 7/162; G03F 7/70466; H01L 21/6715; H01L 21/67173; H01L 21/67225

(57) ABSTRACT

A coating and developing tool includes a coater to coat a semiconductor wafer with a photoresist layer, a developer to develop a latent image formed in a photoresist layer coating a semiconductor wafer, and a robotic transfer arm to transfer a semiconductor wafer between the coating and developing tool and a photolithography exposure scanner. The robotic transfer arm includes a wafer transfer assembly mounted to the robotic transfer arm to send the wafer from the robotic transfer arm to the coating and developing tool. The wafer transfer assembly includes at least one wafer holder and at least one light interrupt sensor mounted on the wafer transfer assembly to detect an edge of the semiconductor wafer using a light beam if the wafer laterally shifts as it is transported by the robotic transfer arm during the transferring of the wafer from the photolithography exposure scanner to the coating and developing tool.

### BACKGROUND

The following relates to the photolithography arts, to the wafer handling arts, to the semiconductor fabrication arts, and to related arts.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A-1C diagrammatically illustrate a coater and developer tool including an IRA (Interface Block Robotics Arm) according to an embodiment of this disclosure.

FIGS. 2A-2G diagrammatically illustrate various aspects of IRA wafer holders according to embodiments of this disclosure.

FIGS. 3A and 3B diagrammatically illustrate other various aspects of IRA wafer holders according to embodiments of this disclosure.

FIGS. 4A-4K illustrate an example embodiment of a track IRA advance wafer holder device and system according to this disclosure.

FIGS. 5A-5K diagrammatically illustrate various steps to assemble or fabricate an IRA advance wafer holder according to this disclosure.

FIG. 6A diagrammatically illustrates a wafer centered left and right “no alarm” condition (Left Shift Threshold Value: 190; Left Shift Actual Display Value 999, and Right Shift Threshold Value: 190; Right Shift Actual Display Value 999) according an embodiment of this disclosure, and FIG. 6B diagrammatically illustrates a wafer off center 0.5 mm to the left “no alarm” condition (Left Shift Threshold Value: 190; Left Shift Actual Display Value 999, and Right Shift Threshold Value: 190; Right Shift Actual Display Value 999) according an embodiment of this disclosure, wherein the IRA arm is longitudinally extended 3 cm.

FIG. 7A diagrammatically illustrates a wafer centered left and right “no alarm” condition (Left Shift Threshold Value: 190; Left Shift Actual Display Value 600, and Right Shift Threshold Value: 190; Right Shift Actual Display Value 600) according an embodiment of this disclosure, and FIG. 7B diagrammatically illustrates a wafer off center 0.5 mm to the left “alarm” condition (Left Shift Threshold Value: 190; Left Shift Actual Display Value 0, and Right Shift Threshold Value: 190; Right Shift Actual Display Value 999) according an embodiment of this disclosure, wherein the IRA arm is longitudinally extended 2 cm.

FIG. 8A diagrammatically illustrates a wafer centered left and right “no alarm” condition (Left Shift Threshold Value: 190; Left Shift Actual Display Value 200, and Right Shift Threshold Value: 190; Right Shift Actual Display Value 200) according an embodiment of this disclosure, and FIG. 8B diagrammatically illustrates a wafer off center 0.5 mm to the left “alarm” condition (Left Shift Threshold Value: 190; Left Shift Actual Display Value 0, and Right Shift Threshold Value: 190; Right Shift Actual Display Value 600) according an embodiment of this disclosure, wherein the IRA arm is longitudinally extended 1 cm.

FIG. 9A diagrammatically illustrates a wafer centered left and right “no alarm” condition (Left Shift Threshold Value: 190; Left Shift Actual Display Value 400, and Right Shift Threshold Value: 190; Right Shift Actual Display Value 400) according an embodiment of this disclosure, and FIG. 9B diagrammatically illustrates a wafer off center 0.5 mm to the left “alarm” condition (Left Shift Threshold Value: 190; Left Shift Actual Display Value 0, and Right Shift Threshold Value: 190; Right Shift Display Value 999) according an embodiment of this disclosure, wherein the IRA arm is longitudinally extended 0 cm.

FIG. 10A diagrammatically illustrates an example wafer shift position (Shift Threshold Value: 200; Actual Display Value 150), which triggers and produces an alarm, where the wafer blocks only a portion of the light beam of the light interrupt sensor, and FIG. 10B diagrammatically illustrates an example wafer shift position (Shift Threshold Value: 200; Actual Display Value 999), which does not produce an alarm, where the wafer does not block any portion of the light beam of the light interrupt sensor.

FIG. 11A shows an example of an AMP (Amplifier) (KEYENCE LV-N11N) used with transmitter and receiver sensor pair (KEYENCE LV-S71) according to an example embodiment, and 11B diagrammatically illustrates light beam characteristics of a nonlimiting illustrative light interrupt sensor.

FIGS. 12A-12D diagrammatically illustrate single threshold algorithms and control methods for an IRA advance wafer holder according to example embodiments of this disclosure.

FIGS. 13A-13D diagrammatically illustrate double threshold algorithms and control methods for an IRA advance wafer holder according to an example embodiments of this disclosure.

FIG. 14A diagrammatically illustrates a Track IRA according to an example embodiment of this disclosure, including the indicated axis of rotation of the IRA, and FIG. 14B diagrammatically illustrates a Track IRA module for use in a Coater and Developer cluster, or other wafer processing cluster, according to an example embodiment of this disclosure.

FIG. 15 is a flow chart illustrating an example semiconductor wafer processing embodiment according to this disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The term “processing unit” as used herein, refers to a processing module, a processing device, or a processing station of a wafer processing system.

The term “processing module,” as used herein, refers to a unit or a device of a wafer processing system that adds or removes materials to/from a wafer.

The term “processing station,” as used herein, refers to a unit or device of a wafer processing system that alters one or more physical characteristics of a wafer but does not modify materials on the wafer, for example, a heating or cooling plate that temporarily changes the temperature of the wafer, or a static discharge device.

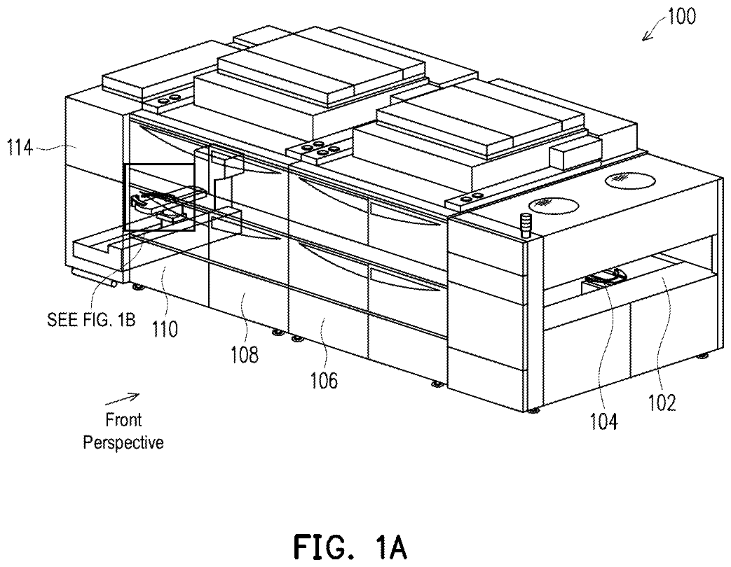

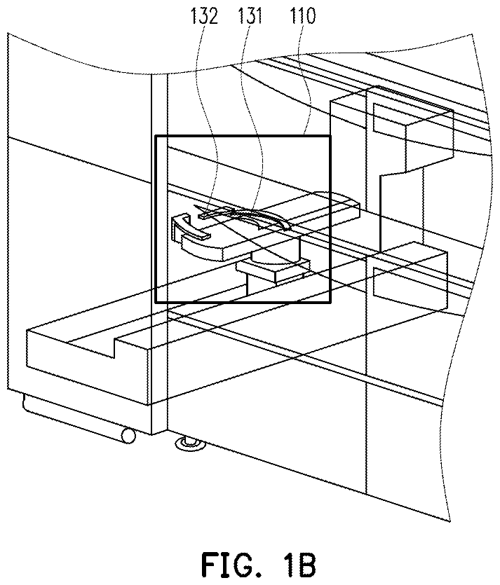

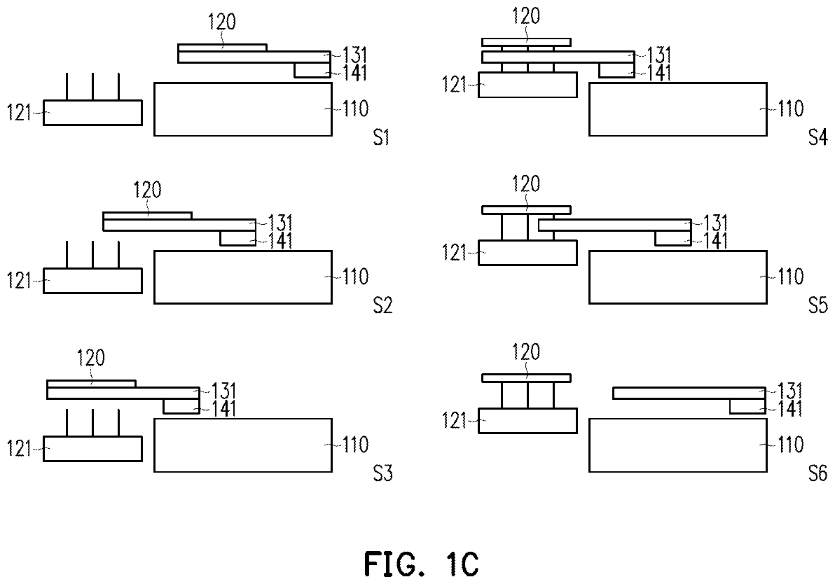

Throughout this disclosure the terms left and right are used in reference to the location position of a wafer holder and advance wafer holder. It is to be understood that left and right refer to locations from the perspective of an observer looking toward the front of Track Tool 100, Scanner 114, and robotic transfer arm 110, (See FIG. 1A).

FIG. 1 illustrates a wafer processing system 100 that can be part of a semiconductor manufacturing line, in accordance with some embodiments. According to the example described herein, the coater 106, developer 108, and robotic transfer arm 110 (for example, implemented as an Interface Block Robotics Arm, IRA, tool 110) is manufactured by TOKYO ELECTRON LIMITED, model family ACT-8. The wafer processing system is a coater 106, developer 108, and scanner (exposure) tool 114, which includes a track and IRA 110, where the IRA 110 includes an arm that transfers a wafer between a Track (Coater/Developer Tool 100)) and scanner 114 (Exposure tool). The IRA Arm extends and retracts a wafer holder 123 from the track (Coater/Developer), and then the IRA Arm extends and retracts the wafer holder 123 from the scanner 114 (Exposure tool). It is to be understood that the term “Track Tool” as used throughout this disclosure refers to a Coater and Developer tool 100.

As shown in FIG. 1A, the wafer processing system 100 includes Pod Load Port 102 for loading wafers, a Cassette Block Arm 104, a Coater 106 Unit, a Developer Unit 108, an IRA Arm and a Scanner unit 114. Wafer processing system 100 is further equipped with an automated wafer transport system, including a track connecting the other processing units. Semiconductor wafers introduced into processing modules and stations of wafer processing system 100 can include additional materials, such as glass, metal, dielectric, and polymers. A control system operates according to a program stored in a controller to extract individual wafers from a wafer carrier, such as a front opening unified pod (FOUP), and to move the wafers along a track, and into and out of processing units adjacent to the track as processing is completed.

A semiconductor wafer undergoes processing steps by passing though the various units of the track tool and scan tool as illustrated in FIG. 1A. After being cleaned, the semiconductor wafer is first placed within the track tool. The wafer is then placed on the spin coater where it is coated with a photoresist chemical. Before photoresist is applied, the semiconductor wafer can first be coated with hexamethyldisilane (also known as HDMS or Bis(trimethylsilyl)amine), which promotes adhesion of photoresist to the surface of the semiconductor wafer. After spin coating, and any other appropriate processing, the wafer is then transferred into the scan tool, aligned with a photomask in the alignment stage, and exposed to electromagnetic radiation or an electron beam in the exposure stage. This exposure thus transfers a pattern on the photomask into the chemical matrix of the photoresist. After exposure, the semiconductor wafer is then transferred back to the track tool, which transports the water to the developer unit for developing the applied photoresist using chemical solvents. The chemical solvents used in developing unit selectively remove the exposed or unexposed regions of photoresist, depending on whether the positive or negative photoresist is used. Finally, further processing may be performed, including but not limited to, a baking step to hardens the developed photoresist image to withstand harsh environments expected to be encountered in implantation or etching processes. The wafer can then be processed, for example implanted or etched, with the pattern in place; and after such processing the photoresist layer can be stripped, and additional layers can be formed and patterned in a similar manner. In this way, successive layers of an IC can be built up.

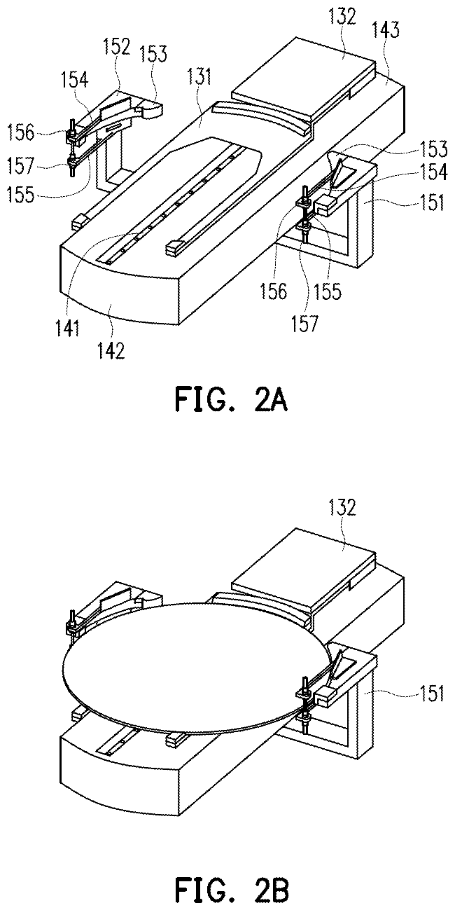

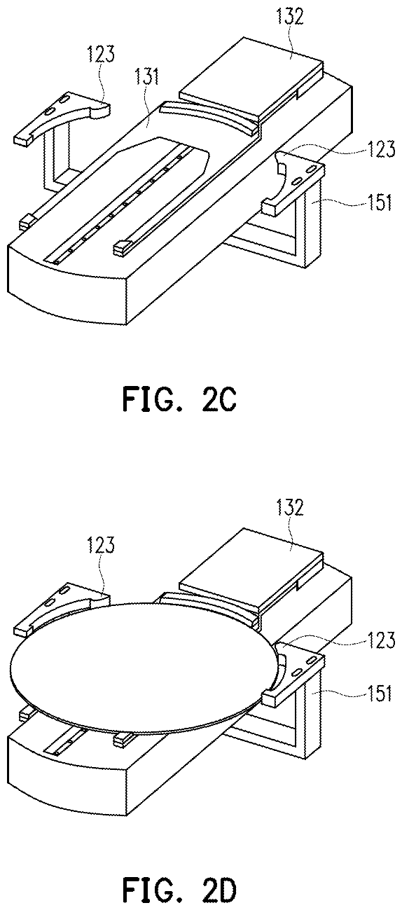

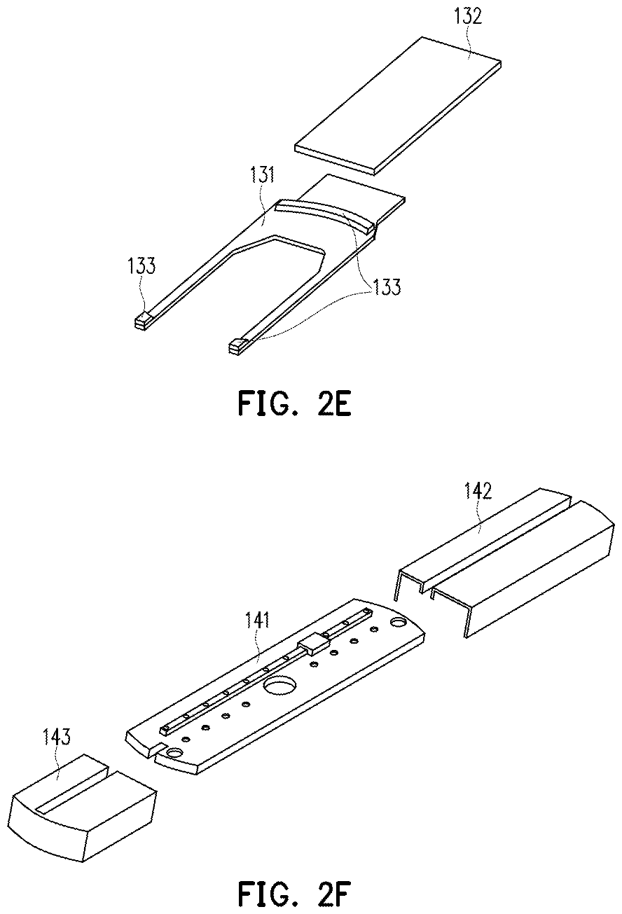

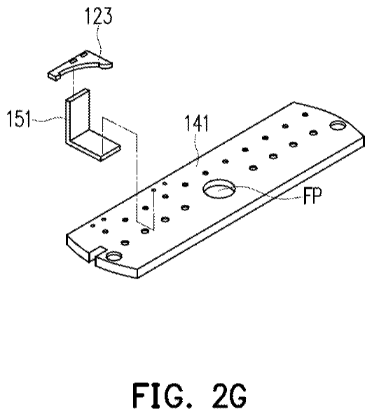

This disclosure, and the embodiment described herein relates to the transport of a wafer, used in semiconductor fabrication, 1) from the Track Tool to the IRA arm, 2) from the IRA arm to the Scanner for exposure of the photoresist according to a photomask, and 3) from the Scanner back to the Track Tool for further processing, for example developing of the applied photoresist material. The IRA arm includes, in part, an IRA pincette 131 and wafer holder assembly that is attached to an IRA linear motion guide 141 that extends and retracts the IRA arm to receive and send wafers. A previous embodiment includes a wafer holder 123 and IRA pincette 131 as shown in FIG. 1B, FIG. 2C, without a wafer, and FIG. 2D with a wafer.

As shown in FIG. 1B, the IRA arm uses a wafer holder 123 to receive and deliver, i.e., send, a wafer from and to the Track Tool and Scanner. To distinguish the disclosed embodiments from previous wafer holders, the disclosed embodiments are referred to as Track IRA Advance Wafer Holders.

With reference to FIG. 1C, shown are a series of operations associated with an IRA 110 sending a wafer 120 to a Scanner 114 for exposure processing.

### IRA 110 Sends Wafer 120 to Scanner:

Step S1: The IRA 110 receives a wafer 120 from the Track Tool, using the wafer pincette 131 to grasp the wafer 120 and the wafer 120 received by wafer holders on the left and right of the IRA arm.

Step S2: The IRA 110 begins to extend its arm, including the attached wafer holder, towards a pedestal 121 used by the Scanner 114 for exposing the wafer.

Step S3: The IRA 110, with its arm extended to a final transfer position, transfers the wafer 120 to the Scanner unit 114 pedestal 121.

Step S4: The IRA 110 disengages the wafer 120, thereby releasing control of the wafer 120 which now rests on the pedestal 121.

Step S5: The IR begins to retract towards a home position.

Step S6: The IRA 110 is now at its final home position and ready to start another wafer transfer process.

IRA 110 RECEIVEs WAFER 120 FROM SCANNER 114: The above steps are reversed, Step S6 to Step S1, where initially, (S6) the IRA 110 is at its home position and ready to start a wafer transfer process, then (S5) IRA 110 begins to extend towards the Scanner 114 unit pedestal 121, then (S4) the IRA 110, at its final transfer position, begins to engage the wafer 120, and (S3) engages the wafer 120, thereby taking control of the wafer 120 from the pedestal 121. Then (S2) the IRA begins to retract its arm, including the attached wafer holder, towards the home position. Then, (S1) with the IRA at the home position, the IRA is ready to transfer, i.e., send, the wafer 120 from the IRA 110 to the Track Tool for further processing.

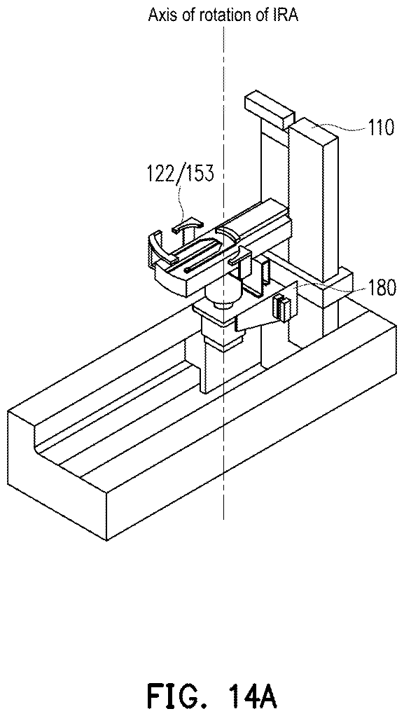

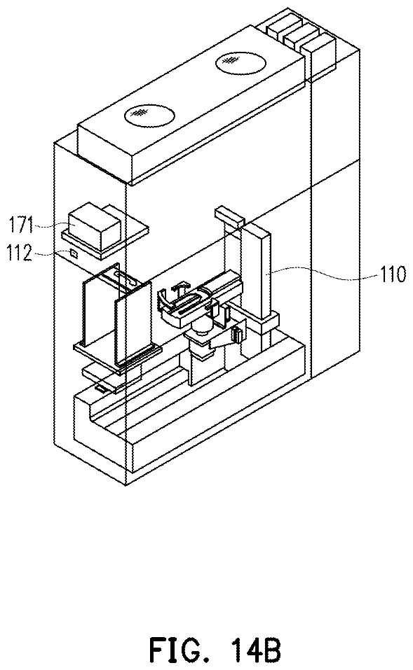

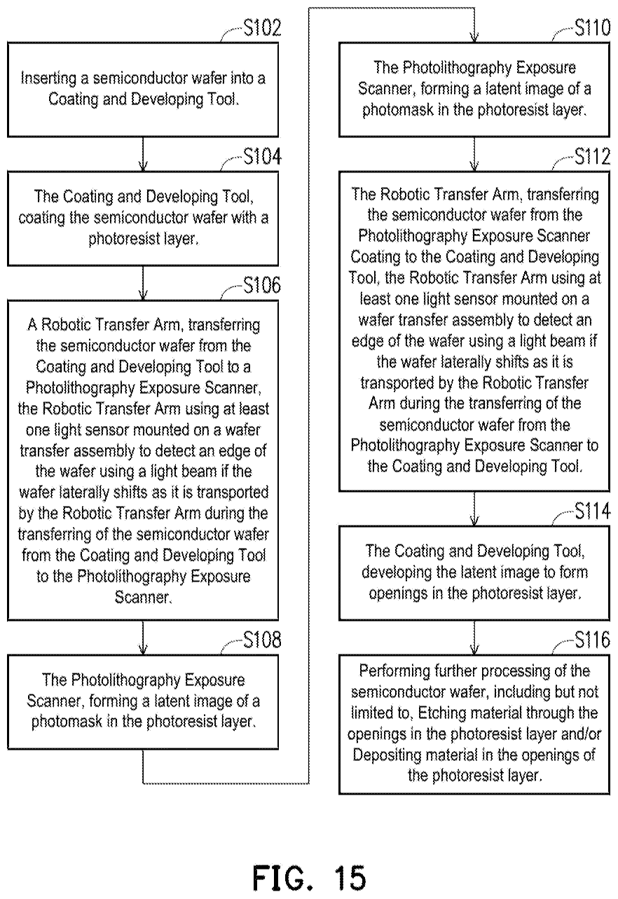

Additional details associated with the IRA wafer transfer operation described above include a rotation of the IRA arm by 180 degrees, according to one nonlimitng example embodiment. To further illustrate, as shown in FIG. 14A, the IRA arm rotates about the indicated axis, to facilitate the lateral placement of the processing units as shown in FIG. 1A. Specifically, the IRA arm rotates 90 degrees counterclockwise to facilitate loading of a wafer 120 on the IRA wafer holder, then rotates 180 degrees clockwise to facilitate transfer of the wafer 120 to the scanner pedestal 121, then the IRA maintains its current position and waits for further instructions(s).

With reference to FIG. 1A, according to an example embodiment, the sequence of operations including IRA rotation are as follow:
1) Load wafer 120 at POD Load Port 102;
2) At track tool (coater 106 & developer 108), Coat wafer 120 with photoresist;
3) IRA 110 receives wafer 120 from track tool (pincette 131 fork facing track tool);
4) IRA 110 rotates 180 degrees so pincette 131 fork faces exposure unit;
5) IRA 110 sends wafer 120 to Exposure unit/Scanner 114;
6) Perform photolithography exposure of wafer 120 at exposure unit/Scanner 114;
7) IRA 110 receives wafer 120 from exposure unit/Scanner 114;
8) IRA 110 rotates 180 degrees so pincette 131 fork faces track tool;
9) IRA 110 sends wafer 120 to track unit; and
10) Wafer photoresist developed using Developer 108.

Some problems associated with the previous embodiment relate to shifting of the wafer during wafer transferring operations as described above. Specifically, the wafer may shift during the transfer operations due to various conditions, including, but not limited to, vibration and wear of the IRA arm and wafer handling components. Some of these unstable conditions can cause stress fragments in the wafer, caused in part by the wafer contacting the wafer holder during transfer operations. Furthermore, previous embodiments do not include an alarm to notify personnel about a wafer shift condition, and they do not include systems to pause the process to address wafer shifting.

This disclosure, and the embodiment described herein provides an IRA advance wafer holder, system and control methods to detect wafer position and wafer shift associated with an IRA wafer transfer. The IRA advance wafer holder includes the use of left and right light-interrupt sensors mounted to left and right wafer holder brackets, the left and right wafer holder brackets mounted to the IRA linear motion guide, whereby the wafer holder bracket, the wafer holders and the light interrupt sensors travel with the wafer during transfer operations. The function of the light interrupt sensors is detecting wafer shift during transfer operations which needs to be addressed by an EE (Equipment Engineer) in the form of pausing the IRA and/or servicing the IRA equipment.

Some advantages associated with the disclosed embodiments include real time detection of wafer position, thereby ensuring that when the wafer is returned to the IRA, the wafer will not contact the wafer holder; avoiding or minimizing residual stress in the wafer; and/or reducing EE service time associated with replacing wafer holders due to wafer and wafer holder contact.

With reference to FIG. 2A-2G, shown are various aspects of IRA wafer holders according to embodiments of this disclosure.

FIG. 2A shows an example embodiment of an IRA advance wafer holder, without a wafer, and FIG. 2B shows the example embodiment including a wafer 120. The IRA advance wafer holder includes a wafer holder bracket 151 which attaches to a linear motion guide 141 for extension and retraction of the unit to send and receive wafers. Attached to the wafer holder bracket 151 are a left advance wafer holder assembly and a right advance wafer holder assembly. Each of the left and right advance wafer holder assemblies includes a wafer holder base 152 attached to the wafer holder bracket 151, wafer holders 153 attached to the wafer holder base 152, a top sensor bracket 154 attached to the topside of the wafer holder base 152, and a bottom sensor 157 attached to the underside of the wafer holder base 152. The top sensor bracket 154 also includes an attached light sensor 156 and the bottom sensor bracket 155 includes a light transmitter 157. The light sensor 156 and the light transmitter 157 together make up a light interrupt sensor 156, 157. While the example embodiment described herein includes a description of an embodiment where the top component 156 is a light receiver 156 and the bottom component 157 is a light transmitter 157, it is to be understood that the light interrupt sensor could instead be implemented by reversing the placement of the light receiver to the bottom sensor bracket 155, and placement of the light transmitter to the top sensor bracket 154 is within the scope of this disclosure.

The left and right light interrupt sensor pairs, i.e., light transmitter 157 and corresponding light receiver 156, are mounted on the sensor brackets such that the light beam emitted from the light transmitter 157 is orthogonal to the face of the semiconductor wafer 120. This arrangement provide a light beam parallel located to the side edge of the wafer 120 as it is being handled by the IRA arm. Normally, without a wafer shifted condition, the light beam transmitted by the light transmitter 157 will not be interrupted by the edge of the semiconductor wafer, or the light beam may only be partially interrupted by the edge of the semiconductor wafer due to acceptable shifting of the wafer 120. In the event the light beam is blocked by the wafer edge or a significant partial block of the beam has occurred, this will block a large portion of all of the light emitted by the light transmitter 157 from reaching the light receiver 156. In this case, a wafer shift condition has occurred that requires attention of the EE, and in some embodiments the operation of the IRA may be paused to enable the EE to correct the situation.

A light interrupt sensor 156, 157 thus includes a light transmitter 157 which transmits a light beam directed to the light receiver 156. For brevity, the combination is sometimes referred to herein as a light interrupt sensor 156 and 157. As will be discussed further below, according to an embodiment, the light interrupt sensors each comprising a light receiver 156 and corresponding light transmitter 157 are operatively connected to an amplifier and control system which are mounted to the IRA 110, for example the IRA arm or IRA chassis. The amplifier may or not be needed to amplify the light sensor signal received from the light sensor 156 for further processing, depending on the specifications of the light interrupt sensors 156 and 157, and the control system is operatively connected to the amplifier and processes the received signals to detect wafer shift conditions and respond appropriately. For example, in the case of wafer shift that require EE intervention, the control system pauses the IRA alarm and may notify the EE or other appropriate personnel that an alarm condition exists that requires attention. and detect wafer shift conditions that a wafer shift alarm condition.

For comparison purposes, FIG. 2C (without wafer) and FIG. 2D (with wafer 120) illustrates the previous wafer holder design which includes only a wafer holder bracket 151 with attached wafer holder 153. In other words, the previous design does not include the wafer shift detection components previously described, i.e., left, and right sensors and operatively associated bracket hardware attached to a wafer holder base 152.

With reference to FIG. 2E-2G, illustrated are various details of the advance wafer holder described. FIG. 2E illustrates the pincette base 132, pincette 131, and pincette wafer pad 133 assembly. FIG. 2F illustrates the linear motion guide 141 and linear motion guide covers 142 and 143. FIG. 2G illustrates the linear motion guide 141 wafer holder bracket 151 and wafer holder arrangement for the previous design, however the wafer holder bracket 151 and linear motion guide 141 arrangement shown applies to the advance wafer holder disclosed herein. The wafer holder shown is simply modified/replaced with the advance wafer holder components previously described. Specifically, the previous design wafer holder 123 is modified to include a wafer holder base 152, and top and bottom sensor brackets 154 and 155 and sensors attached thereto.

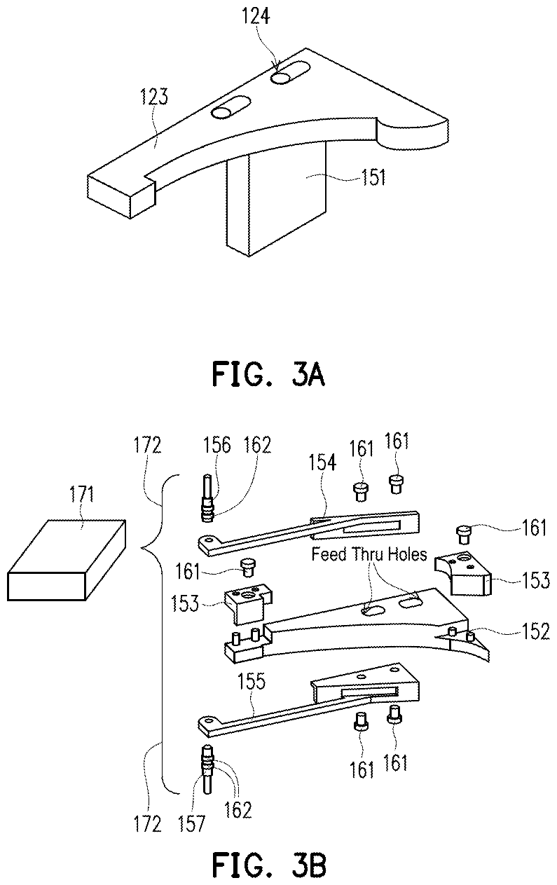

With reference to FIG. 3A, provided is another illustration of a previous wafer holder design, including a wafer holder bracket 151, and wafer holder 153. As shown, the wafer holder 153 is attached to the wafer holder bracket 151 using a slotted fastening arrangement 124 to provide some adjustment of the wafer holder 153. As shown in FIG. 3B, this slotted fastening arrangement can be incorporated into the disclosed advance wafer holder for fastening the wafer holder base 152 to the wafer holder bracket 151.

FIG. 3B also illustrates an exploded view of the advance wafer holder disclosed herein. Specifically, shown is a signal controller 171, cabling from the signal controller 171 to the top light receiver sensor 156 and bottom light transmitter 157, and the components to mount the light receiver 156 and light transmitter 157 of the light interrupt sensor to the wafer holder bracket 151. In addition to the signal controller 171 and sensors, the assembly includes a wafer holder base 152 that attaches to the wafer holder bracket 151 via a slot arrangement 124 using fasteners 161, wafer holders 153 attached to the top side of the wafer holder base 152 using fasteners 161, a top sensor bracket 154 attached to the wafer holder base 152 using fasteners 161 and a bottom sensor bracket 155 attached to the underside of the wafer holder base 152 using fasteners 161. The top receiving sensor uses a nut 162 fastening arrangement to fasten the top sensor to the top sensor bracket 154 through a sensor feed through mounting hole. The bottom transmitting sensor uses a nut fastening arrangement to fasten the bottom sensor to the bottom sensor bracket 155 through a sensor feed through mounting hole. Each of the sensor brackets and wafer holders 153 include feed through holes to facilitate mounting of these components with fasteners 161 and 162 as shown.

While the components described above are not limited to a particular material, according to an example embodiment, the advance wafer holder base 152 is made of an aluminum alloy, the sensor brackets are made of stainless steel and the wafer holders 153 are made of Polyoxymethylene (POM).

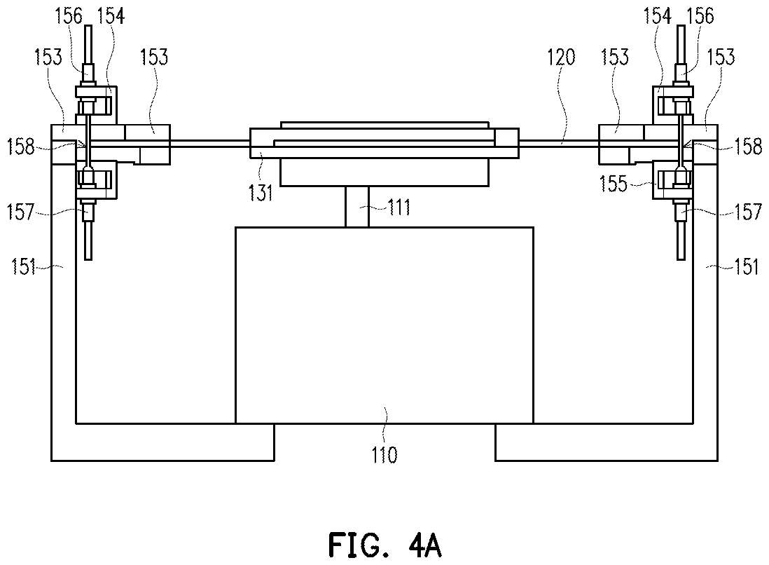

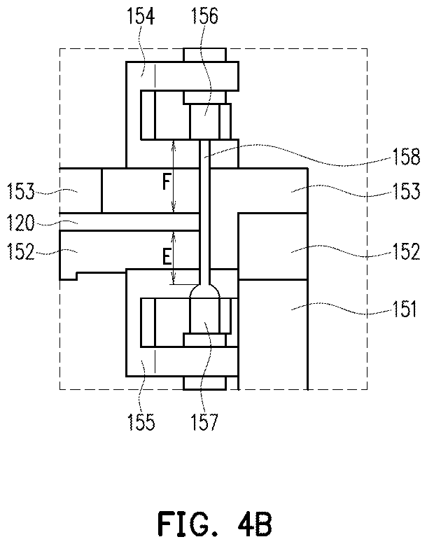

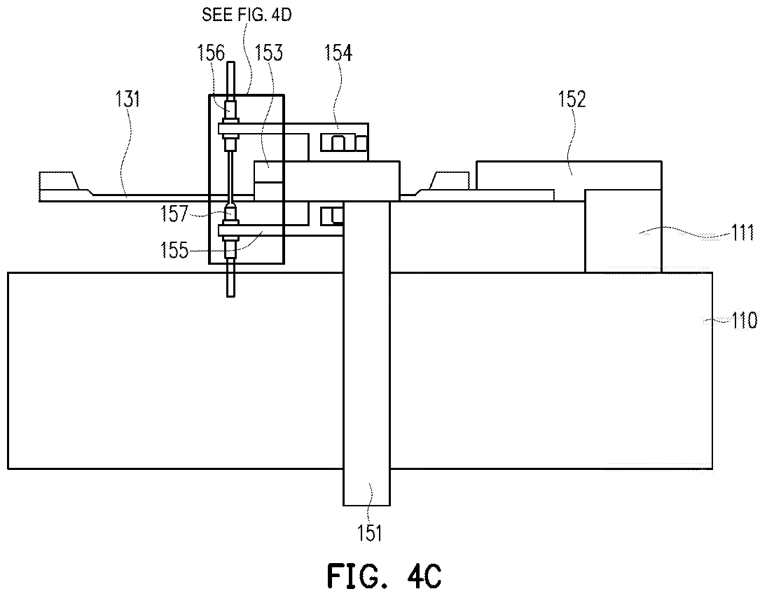

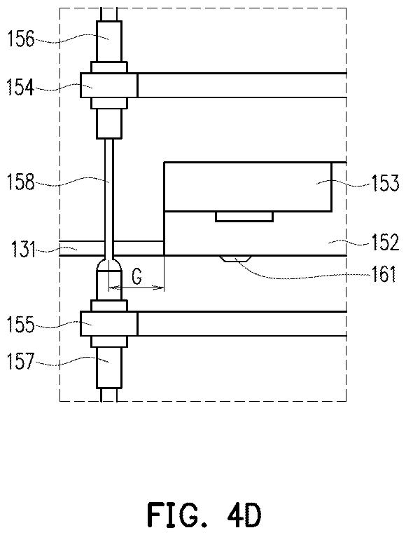

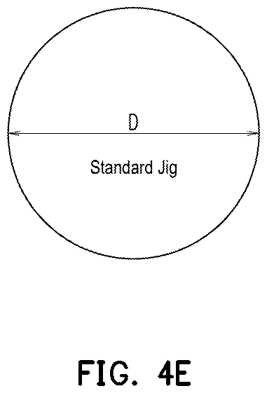

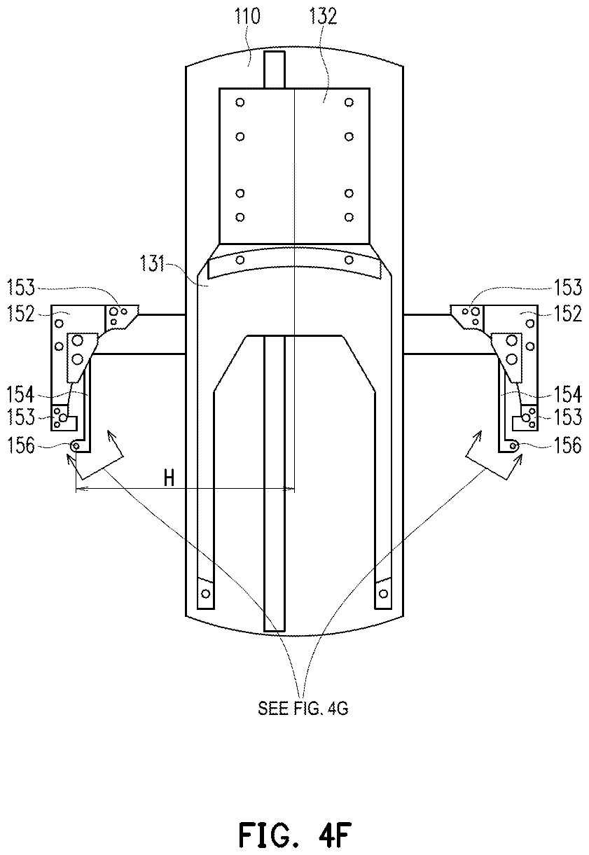

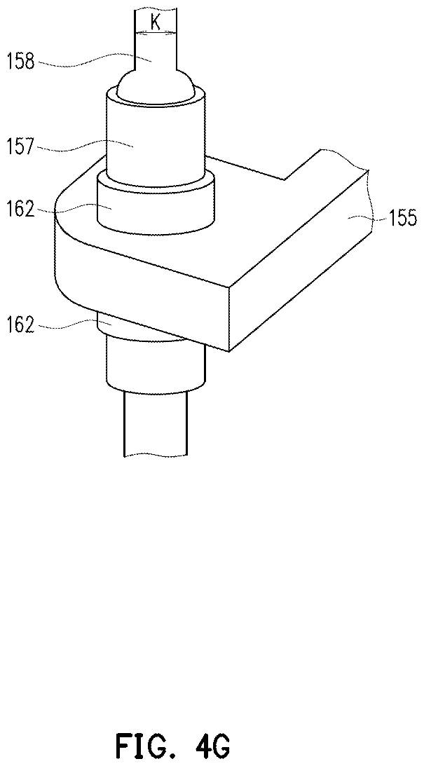

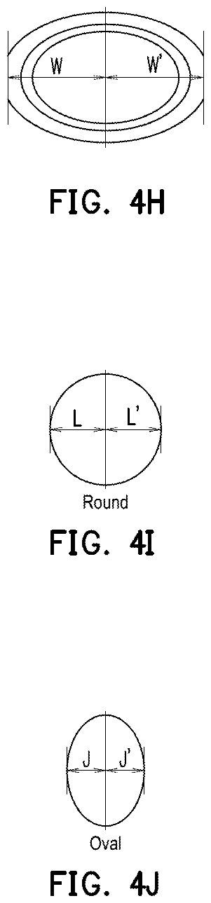

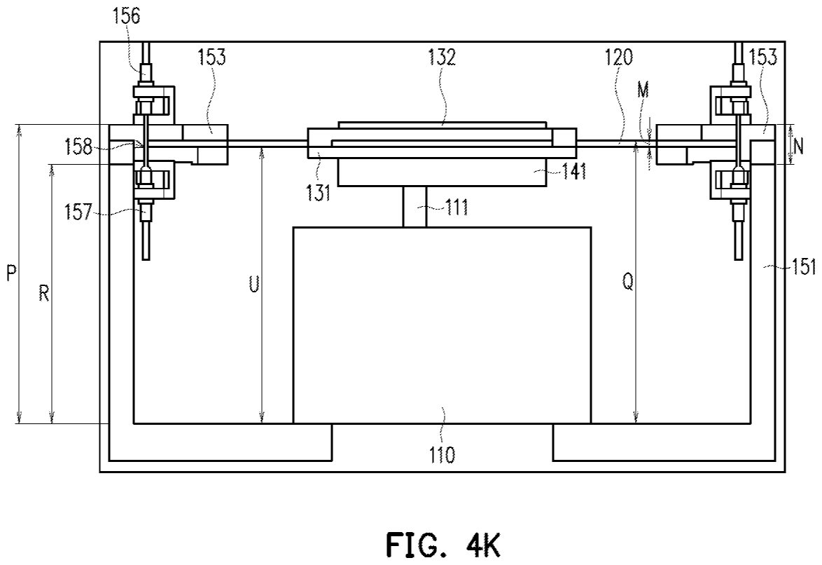

FIGS. 4A-4K illustrate various other aspects of an example embodiment of a track IRA advance wafer holder device and system according to this disclosure.

FIG. 4A is a front view of an IRA advance wafer holder arrangement according to an example embodiment. The IRA advance wafer holder arrangement includes an IRA arm 111 and wafer holder brackets 151. In addition, the arrangement includes a left IRA advance wafer holder and a right IRA advance wafer holder. Each of these advance wafer holders include a wafer holder base 152, wafer holders 153, top and bottom sensor bracket 154 and 155 and top and bottom components of the light interrupt sensors 156 and 157 attached to the respective top sensor mounting bracket and bottom sensor mounting bracket. Referencing FIG. 2E-2G and FIG. 4a, one end of the IRA arm 111 is fixed to LM guide 141 and the other end is fixed to pincette 131/133. An IRA theta motor can be installed below LM guide 141 for rotating the IRA arm 111 about fixed point FP (hole) located at the center or near the center of LM guide 141. Identical reference characters are used for similar components included in the left and right advance wafer holder arrangements.

Further shown is a wafer 120 being carried by the IRA arm. FIG. 4B is a detail view of the interface of the wafer edges and the advance wafer holder, where the light beam 158 emitted by the light transmitter 157 is only partially obstructed from reaching the light receiver 156 by the wafer 120, indicating a non-alarm or normal operating condition with minimal wafer shift. Specifically, shown is the wafer 120, wafer holder bracket 151, and wafer holder base 152, as well as components attached thereto, including wafer holders 153, top and bottom sensor mounting brackets, and transmitter sensor 157, receiver sensor 156 and the light beam 158 emitted by the light transmitter 157 and received by the light sensor 156. Dimension E specifies the distance from the bottom of the wafer 120 to the transmission face of the light transmitter, and dimension F specifies the distance from the top of the wafer 120 to the receiving face of the light receiver. As shown, the transmitter sensor is required to be located below the wafer 120 where E>0. The receiving sensor is required to be installed above the wafer 120 where F>0.

FIG. 4C is a side view of the IRA advance wafer holder arrangement according to FIG. 4A, without a wafer carried thereupon and an IRA pincette. The advance wafer holder arrangement includes an IRA arm, IRA arm rotator 111 and wafer holder brackets 151. In addition, the arrangement includes a left IRA advance wafer holder and a right IRA advance wafer holder. Each of these advance wafer holders include a wafer base, wafer holders, top and bottom sensor brackets 154 and 155, the light receiver 156 attached to the top sensor mounting bracket 154 and the light transmitter attached to the bottom sensor mounting bracket 155. Identical reference characters are used for similar components included in the left and right advance wafer holder arrangements. Also shown in this side view, the light interrupt sensor target, i.e., wafer, detection point must be in front of the wafer holders 153. FIG. 4D is a detail view of the interface of the wafer holders 153 and the light beam 158 of the light interrupt sensor, where the sensor target, i.e., wafer, detection point is required be in front of the wafer holders 153 by dimension G, where >0.

FIG. 4E is a top view of a standard wafer jig or wafer with a diameter dimension D; FIG. 4F is a top view of the advance wafer holders arrangement previously described indicating a dimension H which is the distance from the center line of the IRA pincette/pincette base 132 to the light beam 158 edge/center depending on the selected manner of algorithmic detection; and FIG. 4G is a perspective view of the sensor transmitter 157 and transmitted light beam 158, indicating a dimension K representing the transmitted light beam 158 width/diameter. The light interrupt sensor target/wafer detection point can be expressed as ½ (D−K)<H<½ (D+K). While the dimensional relationships described above are not limited to particular values and depend on the dimensions and configuration of the IRA, according to an example embodiment, D=200 mm, K=1.2 mm, where 99.4<100.6<100.6 (½ (D−K)<H<½ (D+K).

FIG. 4H is a top view of a loaded wafer and frame arrangement, referred to as a bumping frame. FIG. 4I is a top view of a round shaped loaded wafer and FIG. 4J is a top view of an oval loaded wafer. The appearance of the loaded object is left-right symmetrical, where W=W′, L=L′, J=J′.

FIG. 4K is another front view of an IRA advance wafer holder arrangement as shown in FIG. 4A, according to an example embodiment. The IRA advance wafer holder arrangement includes an IRA arm 111 and wafer holder brackets 151. In addition, the arrangement includes a left IRA advance wafer holder and a right IRA advance wafer holder. Each of these advance wafer holders include a wafer holder base 152, wafer holders 153, top and bottom sensor brackets 154 and 155 and top and bottom light interrupt sensors 156 and 157 attached to the sensor mounting brackets 154 and 155. Identical reference characters are used for similar components included in the left and right advance wafer holder arrangements.

Further shown are dimension M (Wafer thickness) representing the thickness of the wafer; dimension N (Wafer holder thickness) representing the distance from the top of the wafer holder to the bottom surface of the wafer holder; dimension P (Wafer holder highest point) representing the distance from the top of the wafer holder to the top surface of the wafer bracket; Q (Wafer highest point) representing the distance from the top surface of the wafer holder bracket 151 to the top face of the wafer bracket; dimension R (Wafer holder lowest point) representing the distance from bottom surface of the wafer holder to the top surface of the wafer holder bracket 151; and dimension U (Wafer lowest point) representing the distance from bottom surface of the wafer to the top surface of the wafer holder bracket 151.

Requirements of the advance wafer holder arrangement shown are as follows:
M (Wafer thickness)<Dimension N (Wafer holder thickness); Dimension P (Wafer holder highest point)>Dimension Q (Wafer highest point); and Dimension R (Wafer holder lowest point)<Dimension U (Wafer lowest point).
   While the dimensional relationships described above are not limited to particular values and depend on the dimensions and configuration of the IRA, according to an example embodiment, M=0.8 mm<N=8 mm; P=150 mm>Q=146 mm; and R=142 mm<U=145.2 mm.

While the dimensional relationships described above are not limited to particular values and depend on the dimensions and configuration of the IRA, according to an example embodiment, D=200 mm, K=1.2 mm, where 99.4<H<100.6; (½ (D−K)<H<½ (D+K).

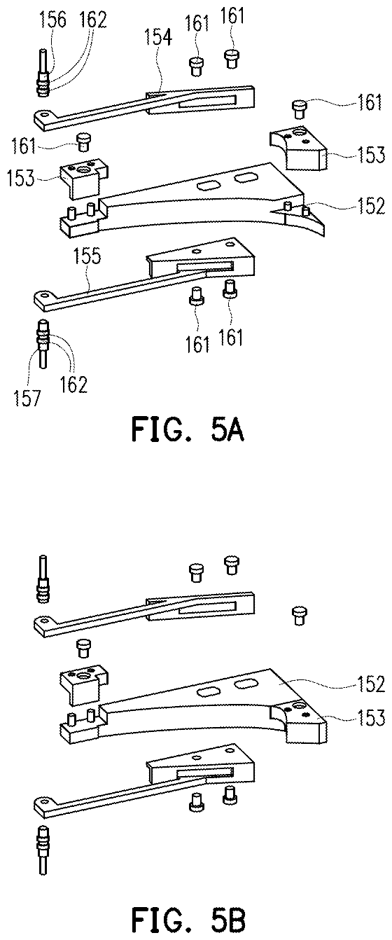

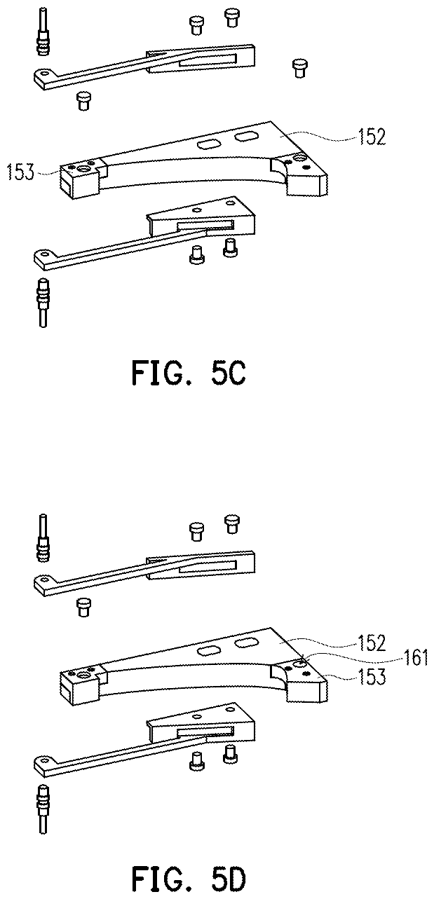

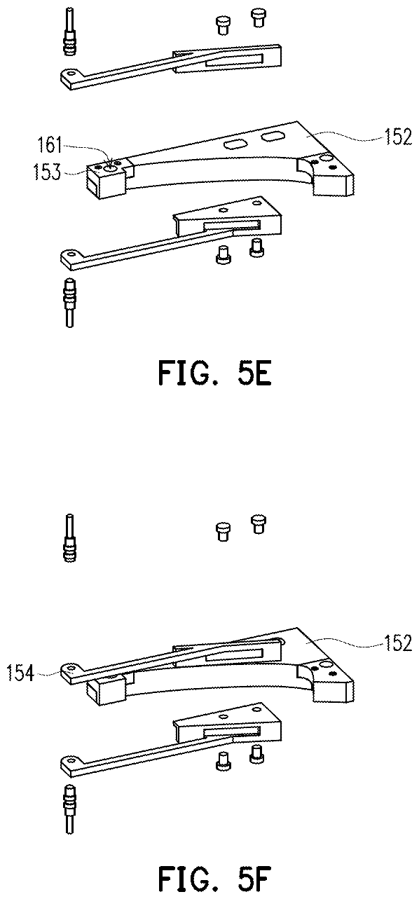

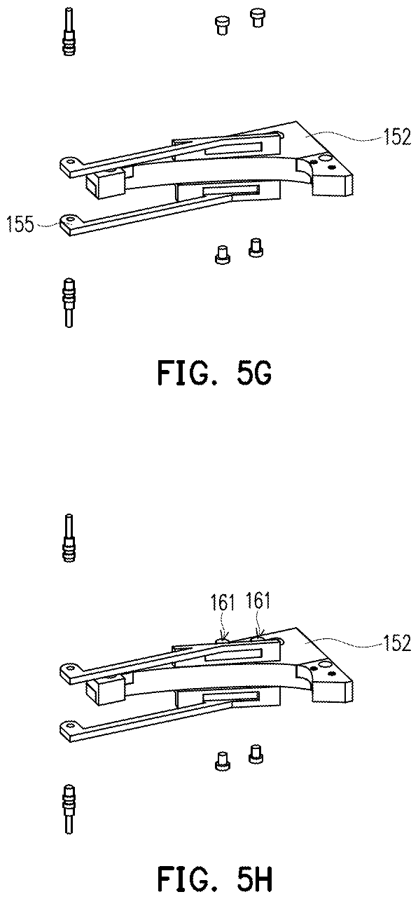

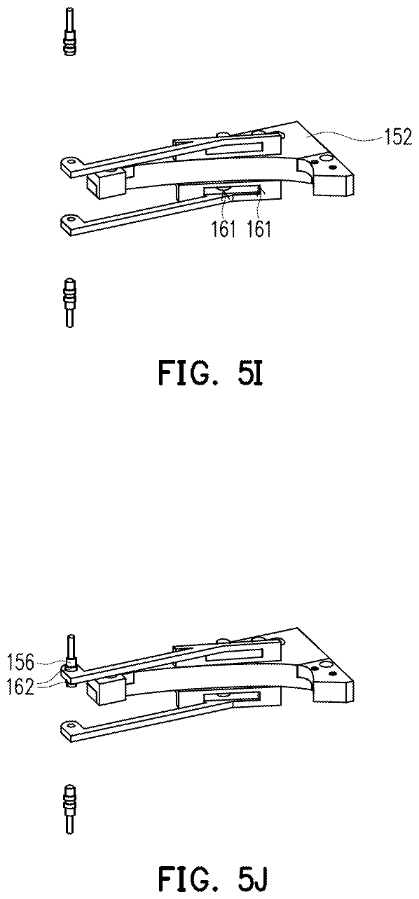

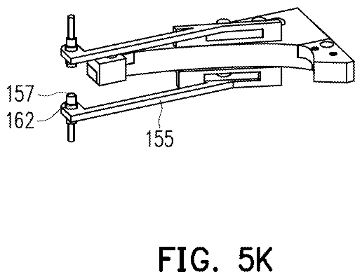

FIG. 5A-5K diagrammatically illustrate various steps to assemble or fabricate an IRA advance wafer holder according to this disclosure.

FIG. 5A is an exploded view of the IRA advance wafer holder including the following: wafer holder base 152; wafer holders 153; top sensor (receiver) bracket 154 and receiver sensor 156; bottom sensor (transmitter) bracket 155 and transmitter sensor 157; and a plurality of fasteners 161 and 162 to assemble advance wafer holder.

FIG. 5B illustrates an initial assembly step that snaps/places a rear wafer holder 153 on the top side of the wafer holder base 152.

FIG. 5C illustrates a next step that snaps/places a front wafer holder 153 on the top side of the wafer holder base 152.

FIG. 5D illustrates a next step that uses a fastener 161 to attach the rear wafer holder 153 to the top side of the wafer holder base 152.

FIG. 5E illustrates a next step that uses a fastener 161 to attach the front wafer holder 153 to the top side of the wafer holder base 152.

FIG. 5F illustrates a next step that snaps/locates the top sensor bracket 154 on the top side of the wafer holder base 152.

FIG. 5G illustrates a next step that snaps/locates the bottom sensor bracket 155 on the underside of the wafer holder base 152.

FIG. 5H illustrates a next step that uses fasteners 161 to attach the top sensor bracket 154 to the top side of the wafer holder base 152.

FIG. 5I illustrates a next step that uses fasteners 161 to attach the bottom sensor bracket to the underside of the wafer holder base 152.

FIG. 5J illustrates a next step that fastens the top receiving sensor 156 to the top sensor bracket 154. This attachment may include a sensor housing top/bottom nut 162 arrangement, where the light receiving sensor 156 extends through a mounting hole in the top sensor bracket 154.

FIG. 5K illustrates a next final step that fastens the bottom light transmitter 157 to the bottom sensor bracket 155. This attachment may include a housing top/bottom nut 162 arrangement, where the light transmitter 157 extends through a mounting hole in the bottom sensor bracket 155.

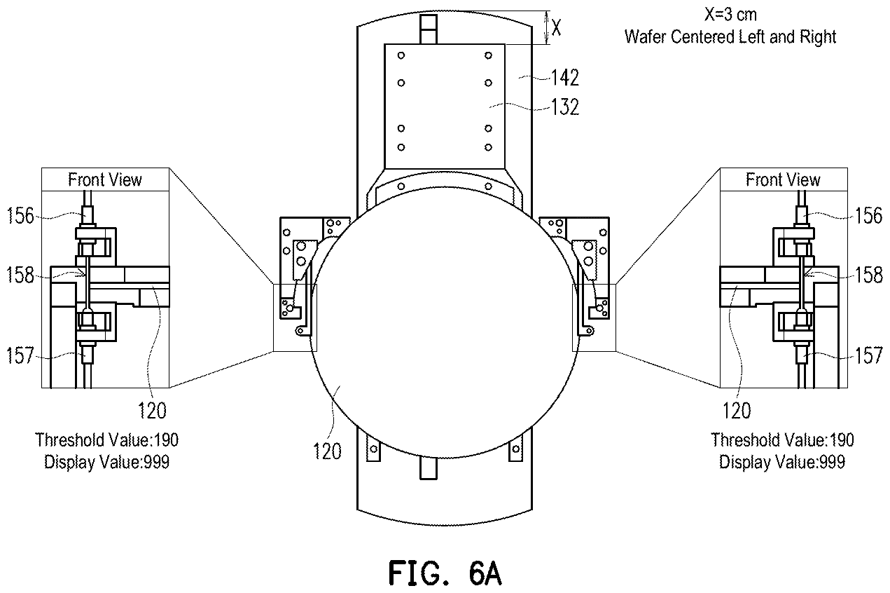

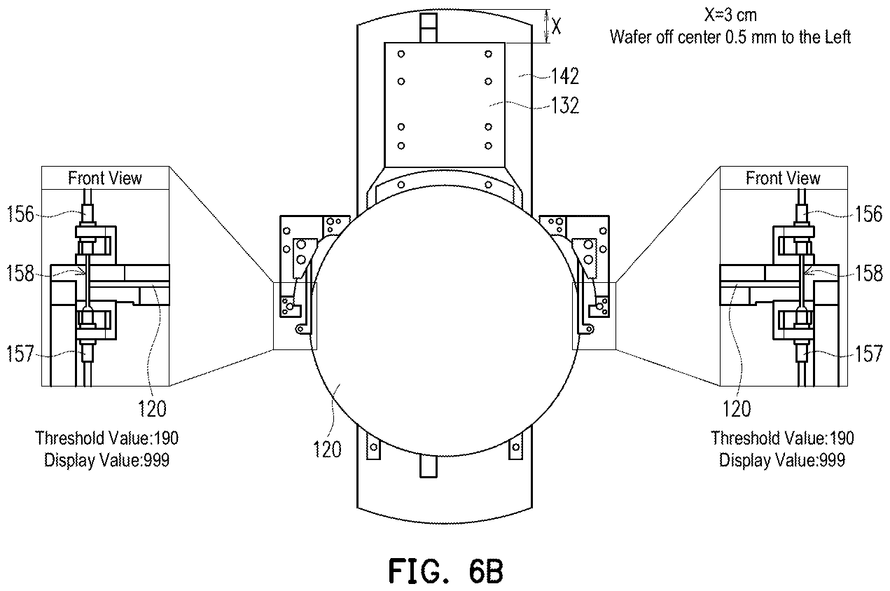

Referring to FIGS. 6A, 6B, 7A, 7B, 8A, 8B, 9A, 9B, 10A and 10B, now is described the operation of an IRA advance wafer holder device and system according to this disclosure and as previously described. Specifically, the operation of the advance wafer light beam 158 detection system applies to detecting wafer shift during a wafer traveling or longitudinal retraction/extending mode. The dimension X shown in the figures is the distance from the IRA advance wafer holder home position, where X=0 indicates the home location, X=1 cm, 2 cm, or 3 cm indicates the advance wafer holder is longitudinally extended/offset from the home location by 1 cm, 2 cm or 3 cm, respectively.

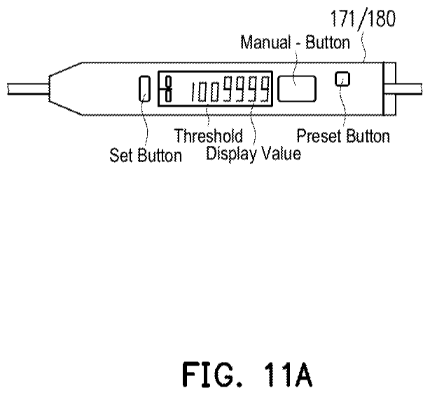

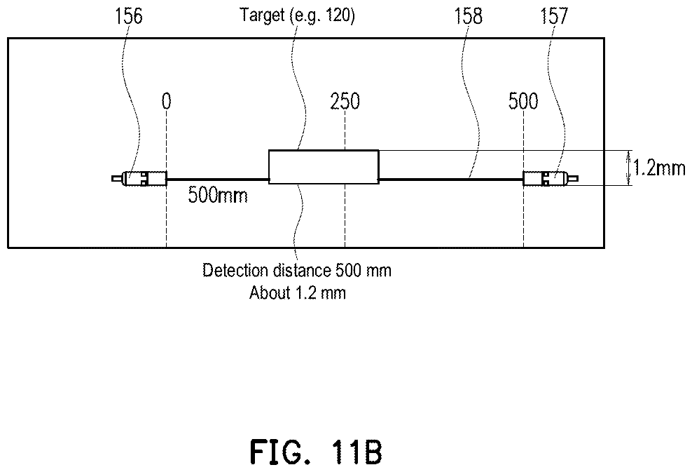

As described above, the top receiving sensors and bottom light transmitters are operatively connected to an amplifier and control system using cables for power and communication. The disclosed embodiments are not limited to a particular amplifier model and light interrupt sensor pairs (transmit and receive pair). FIG. 11A shows an example of an AMP (Amplifier) (KEYENCE LV-N11N) used with transmitter and receiver sensor pair (KEYENCE LV-S71) according to an example embodiment, and 11B diagrammatically illustrates the light beam 158 characteristics, which illustrates light beam 158 detection distance (500 mm) and light beam detection distance (beam about 1.2 mm).

According to the described embodiment, the AMP includes a programmable threshold value that is displayed and represents a minimum intensity of light required to be received by the light receiver 156 before the amplifier sets an output indicating a wafer shift condition that is unacceptable and requires attention. Another actual display value indicates the actual current light intensity received by the sensor receiver 156.

FIG. 6A diagrammatically illustrates a wafer 120 centered left and right “no alarm” condition (Left Shift Threshold Value: 190; Left Shift Actual Display Value 999, and Right Shift Threshold Value: 190; Right Shift Actual Display Value 999) according an embodiment of this disclosure, and FIG. 6B diagrammatically illustrates a wafer 120 off center 0.5 mm to the left “no alarm” condition (Left Shift Threshold Value: 190; Left Shift Actual Display Value 999, and Right Shift Threshold Value: 190; Right Shift Actual Display Value 999) according an embodiment of this disclosure, wherein the IRA arm is longitudinally extended 3 cm.

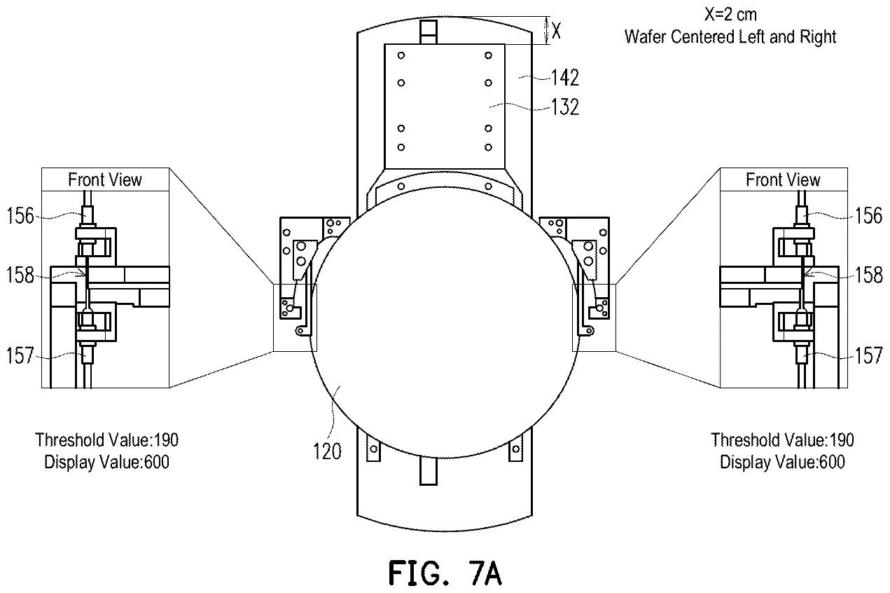

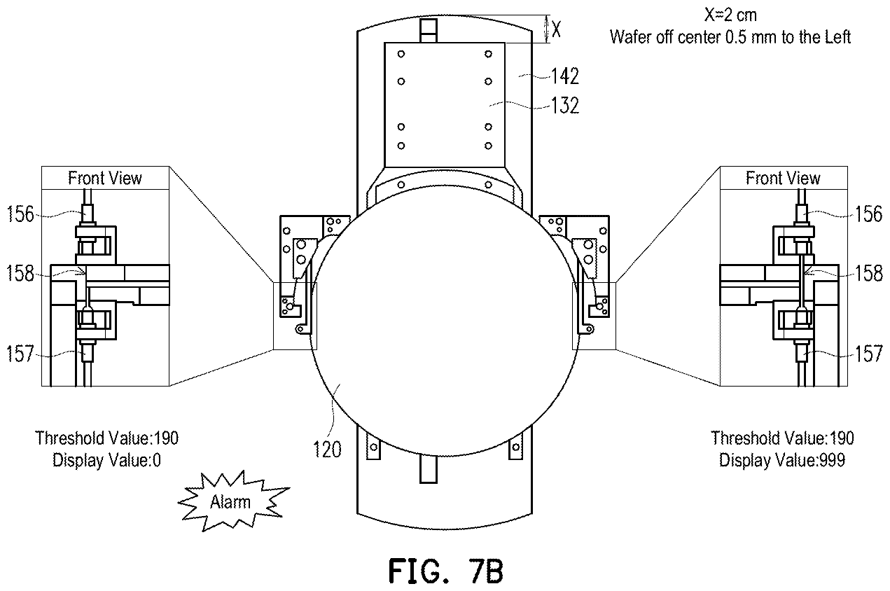

FIG. 7A diagrammatically illustrates a wafer 120 centered left and right “no alarm” condition (Left Shift Threshold Value: 190; Left Shift Actual Display Value 600, and Right Shift Threshold Value: 190; Right Shift Actual Display Value 600) according an embodiment of this disclosure, and FIG. 7B diagrammatically illustrates a wafer 120 off center 0.5 mm to the left “alarm” condition (Left Shift Threshold Value: 190; Left Shift Actual Display Value 0, and Right Shift Threshold Value: 190; Right Shift Actual Display Value 999) according an embodiment of this disclosure, wherein the IRA arm is longitudinally extended 2 cm.

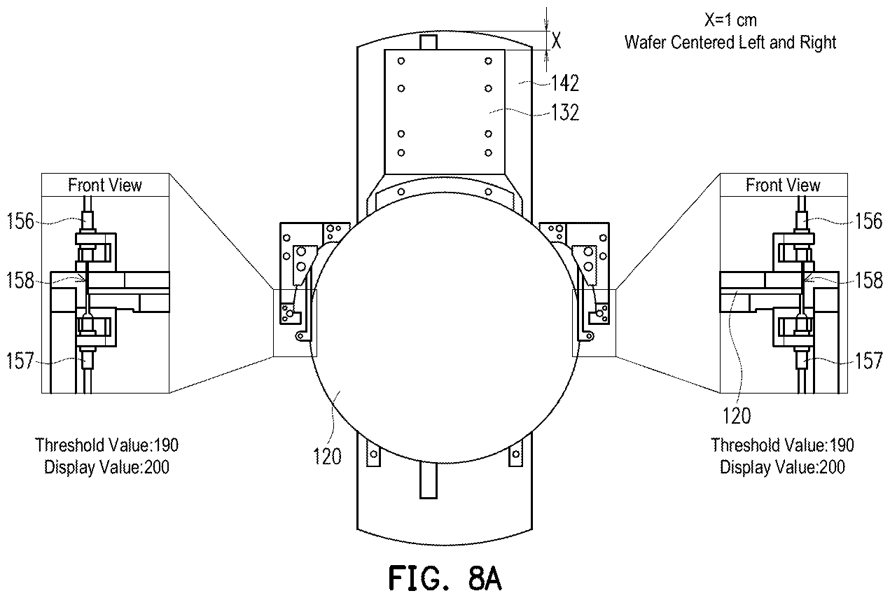

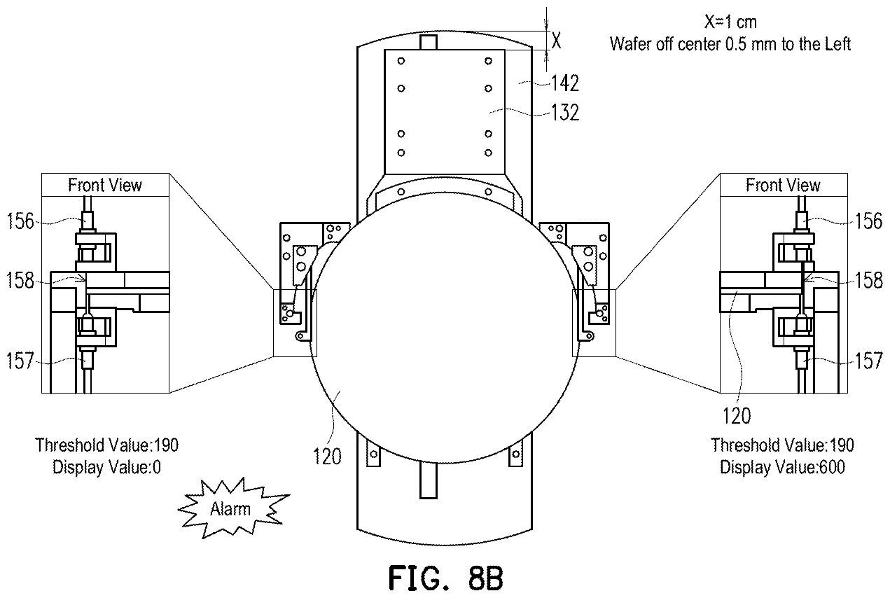

FIG. 8A diagrammatically illustrates a wafer 120 centered left and right “no alarm” condition (Left Shift Threshold Value: 190; Left Shift Actual Display Value 200, and Right Shift Threshold Value: 190; Right Shift Actual Display Value 200) according an embodiment of this disclosure, and FIG. 8B diagrammatically illustrates a wafer 120 off center 0.5 mm to the left “alarm” condition (Left Shift Threshold Value: 190; Left Shift Actual Display Value 0, and Right Shift Threshold Value: 190; Right Shift Actual Display Value 600) according an embodiment of this disclosure, wherein the IRA arm is longitudinally extended 1 cm.

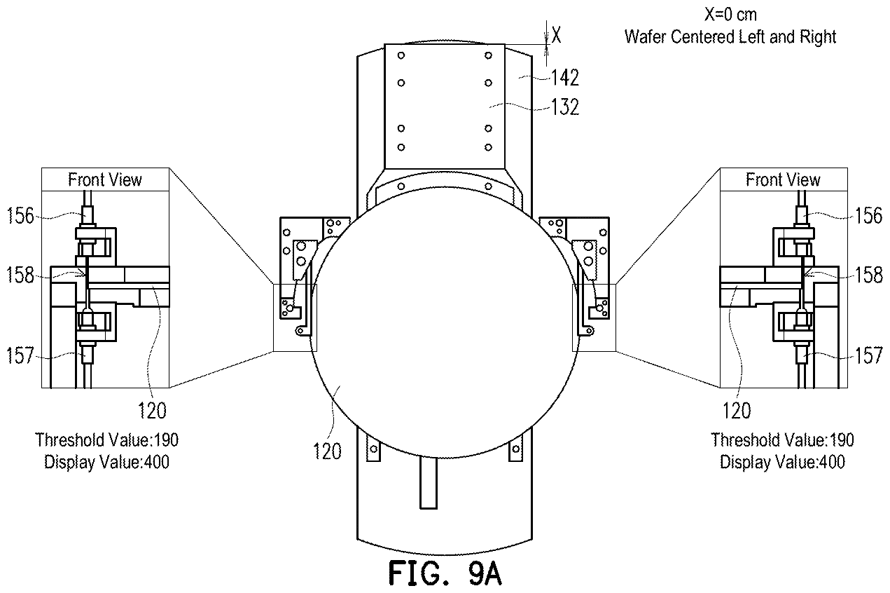

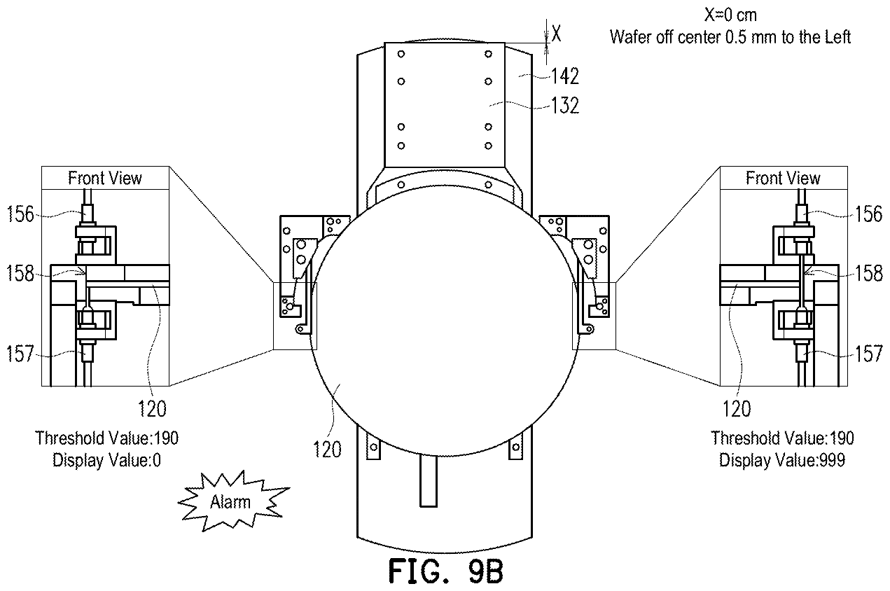

FIG. 9A diagrammatically illustrates a wafer 120 centered left and right “no alarm” condition (Left Shift Threshold Value: 190; Left Shift Actual Display Value 400, and Right Shift Threshold Value: 190; Right Shift Actual Display Value 400) according an embodiment of this disclosure, and FIG. 9B diagrammatically illustrates a wafer 120 off center 0.5 mm to the left “alarm” condition (Left Shift Threshold Value: 190; Left Shift Actual Display Value 0, and Right Shift Threshold Value: 190; Right Shift Actual Display Value 999) according an embodiment of this disclosure, wherein the IRA arm is longitudinally extended 0 cm.

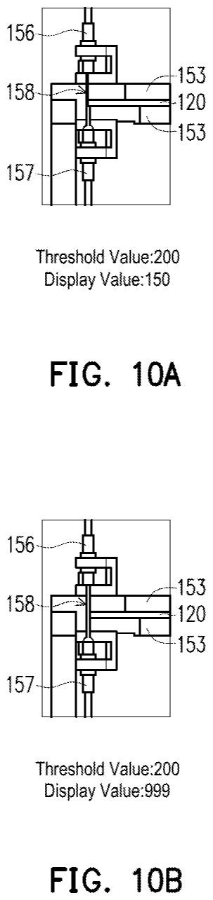

FIG. 10A diagrammatically illustrates another example wafer 120 shift position (Shift Threshold Value: 200; Actual Display Value 150), which triggers and produces an alarm, where the wafer 120 blocks only a portion of the light beam 158, and FIG. 10B diagrammatically illustrates an example wafer shift position (Shift Threshold Value: 200; Actual Display Value 999), which does not produce an alarm, where the wafer 120 does not block any portion of the light beam 158.

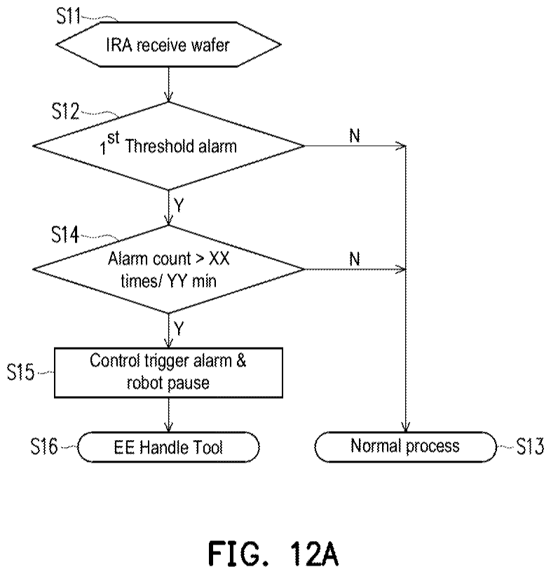

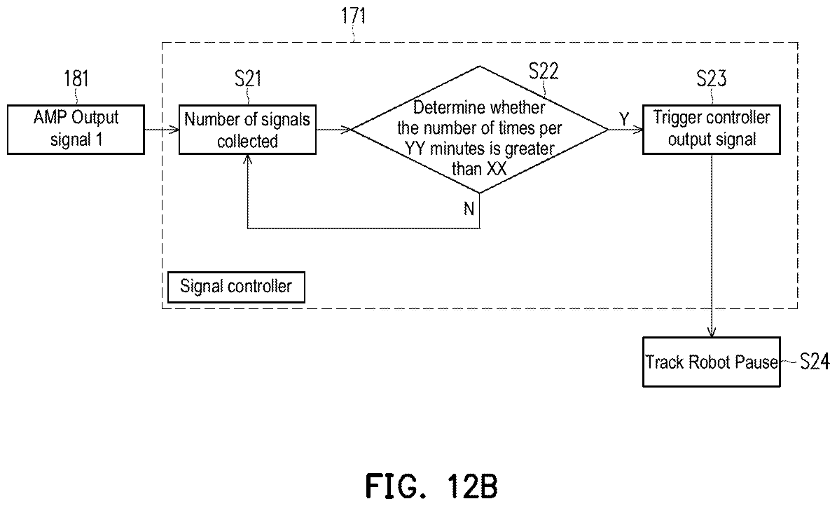

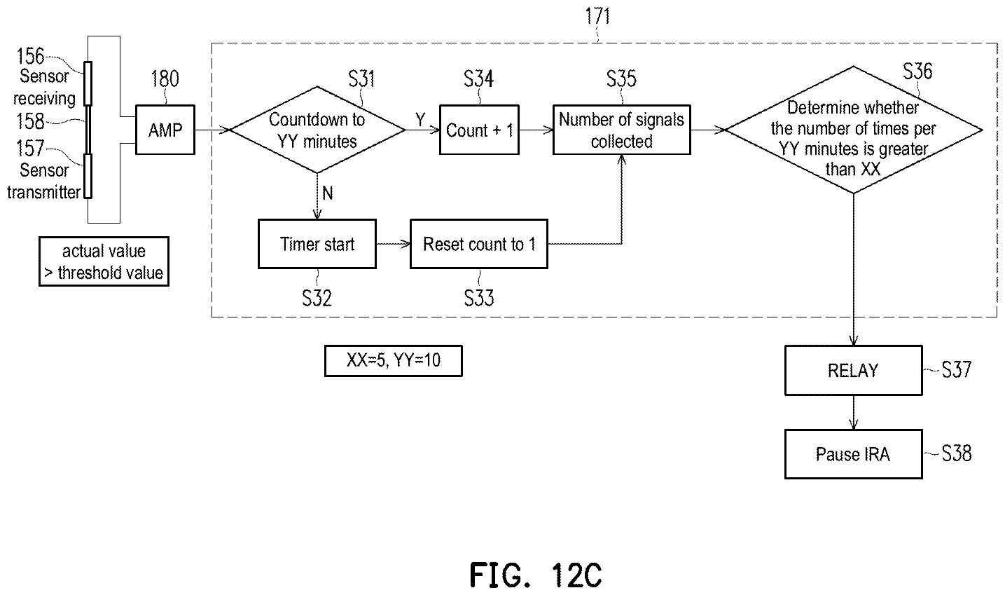

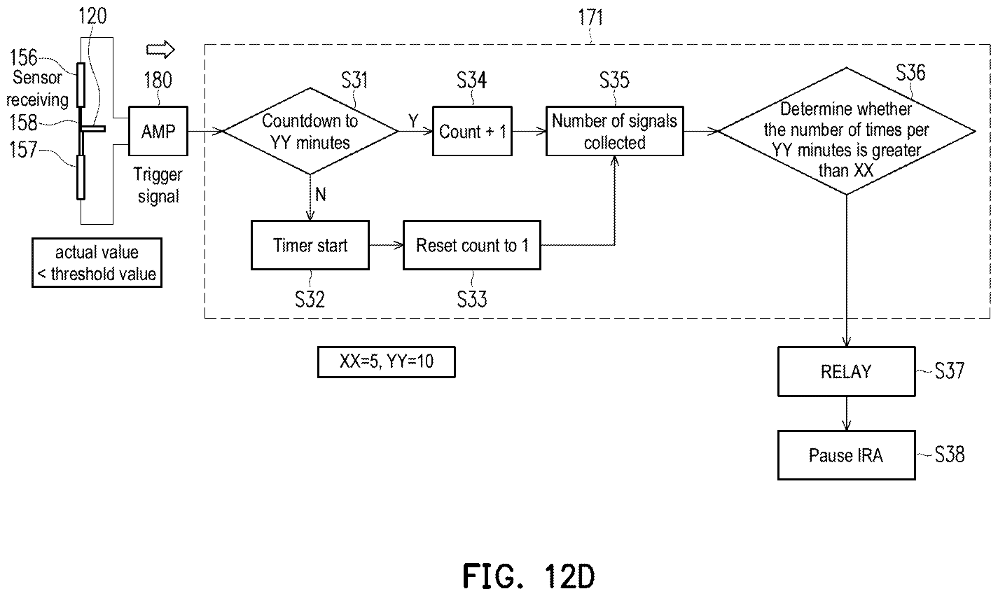

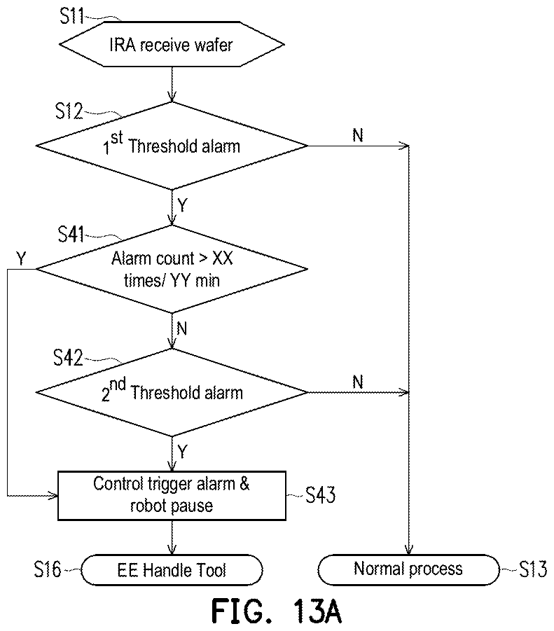

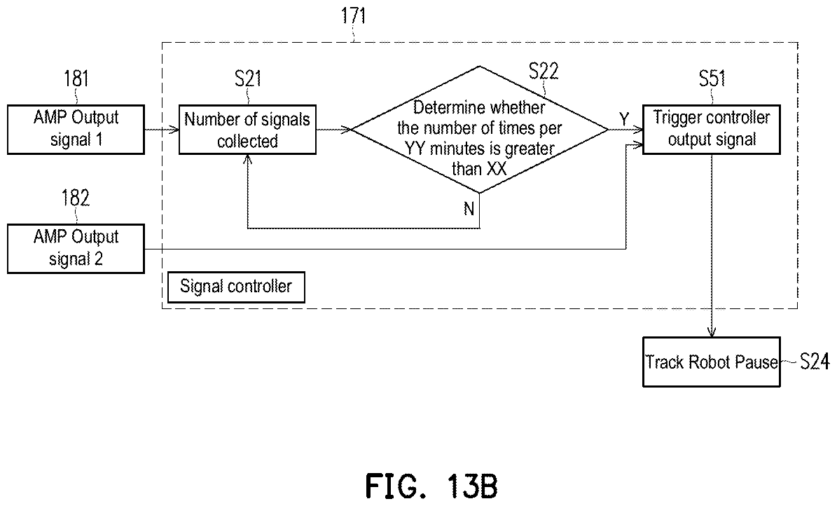

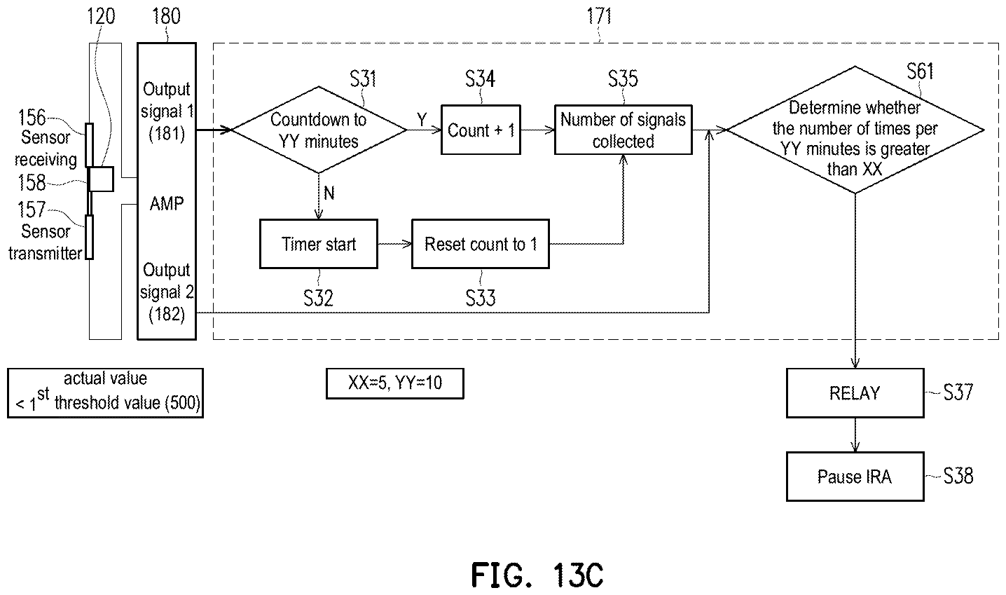

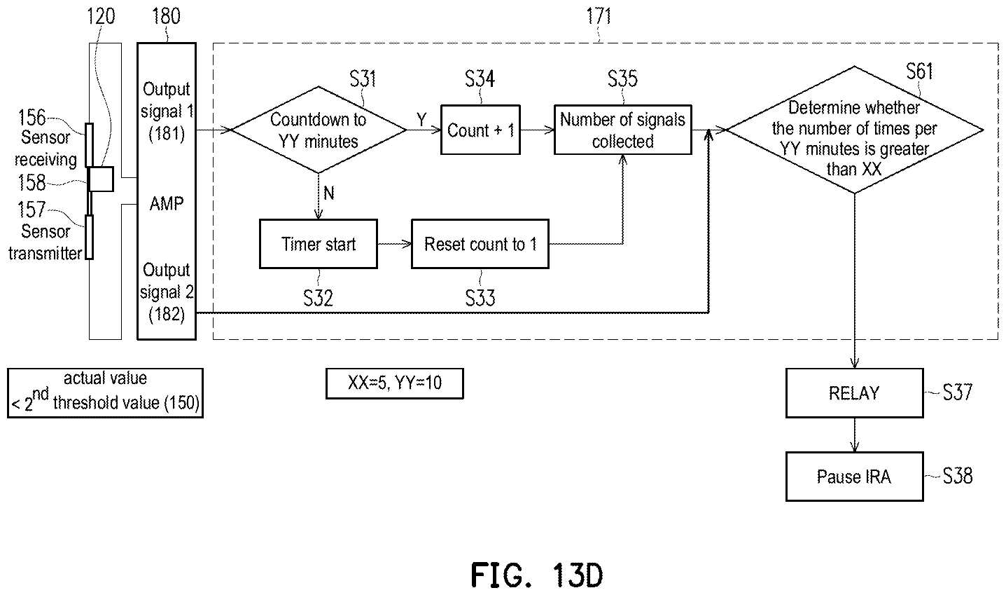

With reference to FIGS. 12A-12D and FIGS. 13A-13D, now is described an IRA advance wafer holder device, as previously described, integrated into a system where top receiving sensors and bottom light transmitters are operatively connected to an amplifier and the amplifier, as previously described, is operatively connected to a control system using cables for power and communications. In addition to the control system monitoring output(s) from the amplifier indicating wafer shift position, the control system is configured to execute computer instructions to perform a method for monitoring the wafer shift state of a wafer and generate an alarm in the event the wafer shift condition is unacceptable and requires manual intervention and/or IRA 110 pausing the movement of the IRA arm. The algorithm descriptions below focus on a single side (left/right) of the IRA advance wafer holder, which includes a single light interrupt sensor including a light transmitter 157 and receiver 156. However, it is to be understood that the algorithms illustrated and described apply equally to the left-side and right-side IRA advance wafer holders which are located to the left and right of the pincette 131, respectively.

FIGS. 12A-12D diagrammatically illustrate a single threshold algorithms and control methods for an IRA advance wafer holder according to example embodiments of this disclosure. For purposes of illustration, the description that follows does not specify a specific threshold value. Threshold values in the range of 0-9998 may be selected depending on the sensitivity and performance desired. Furthermore, the use of other light sensors and amplifier/controller 171 hardware and control algorithms will dictate the appropriate threshold values for the implemented system.

FIG. 12A is a flow chart representative of an algorithm executed by the control system for a single threshold advance wafer holder system. The algorithm operates as follows:

At step S11, the IRA 110 receives a wafer;

At step S12 the algorithm determines if a threshold alarm is present on the light interrupt sensor system amplifier output indicating a wafer shift occurrence or instance. IF No, then the algorithm continues to execute a normal process. IF Yes, then the algorithm proceeds to S14 and begins an Alarm Count process representing the number of wafer shift instances over a predetermined period of time YY. If the Alarm Count (within time YY) is not greater than a predetermined value XX, the algorithm continues to execute a normal process. (S13). If the Alarm Count (within time YY) is greater than a predetermined value XX, the algorithm proceeds to S15 and outputs a trigger alarm and pauses the IRA 110, and notifies an EE, or other personnel, at step S16, to service the equipment.

FIG. 12B is a flow chart representative of another algorithm executed by the control system for a single threshold advance wafer holder system. The algorithm operates as follows:

At step S21, the signal controller 171 monitors the amplifier (AMP) output (AMP Output Signal 1 181) which indicates an instance of wafer shift position (actual light intensity below the threshold value), and counts the number of signals, i.e., instances.

At step S22, the algorithm processes the signal count and determines the number of signal occurrences per YY minutes (timer) is greater than XX instances, for example 5 instances per 10 minutes. However, YY and XX values are not limited to these values and can use any value depending on the desired wafer shift sensitivity detection, such as XX=1-20, or greater, YY=1-20, or greater. IF the number of signal occurrences per YY minutes is greater than XX instances, S22 triggers a controller output and S23 executes a Track Robot Pause indicating the wafer shift is unacceptable and requires intervention. IF the number of signal occurrences per YY minutes is less than or equal to XX instances, S22 returns the algorithm execution to step S21, which continues to collects any AMP output Signals 1 181 output by the AMP.

If a normal process is detected, indicating no abnormal or unacceptable wafer shift, the tool continues to run without any intervention.

If an abnormal wafer shift condition is detected, according to an example embodiment, manual intervention (e.g., EE) is initiated to 1) troubleshoot the IRA 110 for any abnormal jitter or sound which may require the replacement of a motor, driver, lubrication, etc.; 2) adjusting or tuning the threshold value to accommodate the performance characteristics of the IRA 110; and/or 3) other actions, including but not limited to, configure/train IRA 110 systems for abnormal performance of unit.

FIG. 12C is a more detailed flow chart representative of the algorithm executed by the control system for a single threshold advance wafer holder system according to FIG. 12B, where the wafer shift position is normal (actual value greater than threshold value), and XX=5 and YY=10 minutes. As shown in FIG. 12C, the receiving sensor is in a state of receiving the entire transmitter sensor light beam 158 output.

According to this embodiment, the algorithm operates as follows:

At step S31, the signal controller 171 monitors the amplifier (AMP) output which indicates an instance of wafer shift position, which in this case is not triggered/active because the actual light intensity is greater than the threshold value.). At S32 a timer is started, the count is reset to 1 at S33, and step S35 outputs a count of 1 to S36 which determines the number of wafer shift instances is less than or equal to 5 instances per 10 minutes and therefore does not require control of a relay (S37) to pause IRA (S38) and/or notify an EE or other personnel.

FIG. 12D is another more detailed flow chart representative of the algorithm executed by the control system for a single threshold advance wafer holder system according to FIG. 12B, where the wafer shift position is abnormal (actual value less than threshold value), the AMP triggers an output signal indicating a wafer shift condition, and XX=5 and YY=10 minutes. As shown, the receiving sensor is in a state of receiving only a portion of the transmitter sensor light beam 158 output as shown in the figure.

According to this embodiment, the algorithm operates as follows:

At step S31, the signal controller 171 monitors the amplifier (AMP) output which indicates an instance of wafer shift, which in this case is active because the actual light intensity is less than the threshold value. At S32 a timer is started, the count is reset to 1 at S33, and step S35 outputs a count of 1 to S36 which determines the number of wafer shift instances is less than or equal to 5 instances per 10 minutes and therefore does not require control of a relay (S37) to pause IRA (S38). (The AMP output trigger signal is continually monitored by the algorithmic process at S31 during the YY countdown.

IF another trigger signal is detected within the YY countdown, S34 and S35 increments the total count, and continues to increment counter for each occurrence of a trigger signal within the YY countdown time duration. (In this example, 10 minutes) At S36, IF the total count. In the event the number of the total count is greater than XX (e.g., 5), the algorithm determines there is an abnormal wafer shift condition and controls a relay to pause the IRA 110 and/or notify the appropriate personnel for service of the IRA, etc.

FIGS. 13A-13D diagrammatically illustrate double threshold algorithms and control methods for an IRA advance wafer holder according to an example embodiments of this disclosure. For purposes of illustration, the description that follows uses a first threshold value of 500 and a second threshold value of 150, however these threshold values are not limited to these values. Threshold values in the range of 0-9998 may be selected depending on the sensitivity and performance desired. Furthermore, the use of other light sensors and amplifier/controller 171 hardware and control algorithms will dictate the appropriate threshold values for the implemented system.

FIG. 13A is a flow chart representative of an algorithm executed by the control system for a double threshold advance wafer holder system. The algorithm operates as follows:

At step S11, the IRA 110 receives a wafer;

At step S12 the algorithm determines if a first threshold alarm is present on the light interrupt sensor system amplifier output (AMP Output signal 1 181) indicating a wafer shift occurrence or instance. IF No, then the algorithm continues to execute a normal process. IF Yes, then the algorithm proceeds to step S41 and begins an Alarm Count process representing the number of wafer shift instances over a predetermined period of time YY.

At step S41, IF the Alarm Count (within time YY) is greater than a predetermined value XX, the algorithm proceeds to step S15 and outputs a trigger alarm and pauses the IRA 110, and notifies an EE, or other personnel, at S16 to service the equipment.

AT step S41, IF the Alarm Count (within time YY) is not greater than a predetermined value XX, the algorithm continues to step S42 to determine IF a second threshold alarm is present on the light interrupt sensor system amplifier output (AMP Output signal 2 182). IF there is no second threshold alarm, the algorithm proceeds to step S13 and continues to execute a normal process. IF there is a second threshold alarm, the algorithm proceeds to step S43 and outputs a trigger alarm and pauses the IRA 110, and notifies an EE, or other personnel, at step S16, to service the equipment.

FIG. 13B is a flow chart representative of another algorithm executed by the control system for a double threshold advance wafer holder system. The algorithm operates as follows:

At step S21, the signal controller 171 monitors the amplifier output (AMP Output Signal 1 181) which indicates an instance of wafer shift position (actual light intensity below a first threshold value), and counts the number of signals, i.e., instances.

At step S22, the algorithm processes the signal count and determines the number of signal occurrences per YY minutes (timer) is greater than XX instances, for example 5 instances per 10 minutes. However, YY and XX values are not limited to these values and can use any value depending on the desired wafer shift sensitivity detection, such as XX=1-20, or greater, YY=1-20, or greater. IF the number of signal occurrences per YY minutes is greater than XX instances, S22 triggers a controller output and S51 executes a Track Robot Pause at S24 indicating the wafer shift is unacceptable and requires intervention. IF the number of signal occurrences per YY minutes is less than or equal to XX instances, S22 returns the algorithm execution to step S21, which continues to collect any AMP output Signals 1 181 output by the AMP.

Also, at step S51, the signal controller 171 monitors the amplifier output (AMP Output signal 2 182) which indicates an instance of wafer shift position (actual light intensity below a second threshold value, less than the first threshold value). IF AMP Output signal 2 182 is triggered, S51 executes a Track Robot Pause at S24 indicating the wafer shift is unacceptable and requires intervention.

If a normal process is detected, indicating no abnormal or unacceptable wafer shift, the tool continues to run without any intervention.

If an abnormal wafer shift condition is detected, according to an example embodiment, manual intervention (e.g., EE) is initiated to 1) troubleshoot the IRA 110 for any abnormal jitter or sound which may require the replacement of a motor, driver, lubrication, etc.; 2) adjusting or tuning the threshold value to accommodate the performance characteristics of the IRA 110; and/or 3) other actions, including but not limited to, configure/train IRA systems for abnormal performance of unit.

FIG. 13C is a more detailed flow chart representative of another algorithm executed by the control system for a double threshold advance wafer holder system according to FIG. 13B, where the wafer shift position is abnormal (actual value less than first threshold value; actual value greater than or equal to second threshold), and XX=5 and YY=10 minutes. As shown in FIG. 13C, the receiving sensor is in a state of receiving only a portion of the transmitter sensor light beam 158 output. The algorithm operates as follows:

At step S31, the signal controller 171 monitors the amplifier output (AMP Output Signal 1 181) which indicates an instance of wafer shift (actual light intensity below a first threshold value), starts a timer at S32 and S33 for an initially triggered AMP Output Signal 1 181, and outputs a single count to S34 indicating a single instance of wafer shift.

At step S61, the algorithm processes a total signal count from S35 and determines the number of signal occurrences per YY minutes (timer) is greater than XX instances, for example 5 instances per 10 minutes. However, YY and XX values are not limited to these values and can use any value depending on the desired wafer shift sensitivity detection, such as XX=1-20, or greater, YY=1-20, or greater. IF the number of signal occurrences per YY minutes is greater than XX instances, S61 triggers a controller output to control relay at S37 which pauses the IRA (S24) indicating the wafer shift is unacceptable and requires intervention.

Also, at step S61, the signal controller 171 monitors the amplifier output (AMP Output signal 2 182) which indicates an instance of wafer shift position (actual light intensity below a second threshold value, less than the first threshold value). IF AMP Output signal 2 182 is triggered, S61 triggers a controller output to control relay at S37 which pauses the IRA (S24) indicating the wafer shift is unacceptable and requires intervention.

If a normal process is detected, indicating no abnormal or unacceptable wafer shift, the tool continues to run without any intervention.

FIG. 14A diagrammatically illustrates a Track IRA according to an example embodiment of this disclosure, including the indicated axis of rotation of the IRA, and FIG. 14B diagrammatically illustrates a Track IRA module for use in a Coater 100 and Developer cluster, or other wafer processing cluster, according to an example embodiment of this disclosure. These illustrations are provided to aid in the understanding of this disclosure and provide one example of an embodiment that includes the mounting of a signal controller 171, an IRA pause button 112, as shown, to some component of the IRA frame, and the mounting of the previously described amplifier to a surface of the IRA arm. It is to be understood that the embodiments described are not limited to the mounting arrangements shown and the mounting of these devices is not limited to the locations shown. Other mounting locations include can include other surfaces of the IRA arm, IRA frame or surfaces external to the IRA.

With reference to FIG. 15, illustrated is a flow chart of an example semiconductor wafer processing embodiment according to this disclosure.

At processing step S102, Inserting a semiconductor wafer into a Coating and Developing Tool.

At processing step S104, The Coating and Developing Tool, coating the semiconductor wafer with a photoresist layer.

At processing step S106, A Robotic Transfer Arm, transferring the semiconductor wafer from the Coating and Developing Tool to a Photolithography Exposure Scanner, the Robotic Transfer Arm using at least one light interrupt sensor mounted on a wafer transfer assembly to detect an edge of the wafer using a light beam if the wafer laterally shifts as it is transported by the Robotic Transfer Arm during the transferring of the semiconductor wafer from the Coating and Developing Tool to the Photolithography Exposure Scanner.

At processing step S108, The Photolithography Exposure Scanner, forming a latent image of a photomask in the photoresist layer.

At processing step S110, The Photolithography Exposure Scanner, forming a latent image of a photomask in the photoresist layer.

At processing step S112, The Robotic Transfer Arm, transferring the semiconductor wafer from the Photolithography Exposure Scanner Coating to the Coating and Developing Tool, the Robotic Transfer Arm using at least one light interrupt sensor mounted on a wafer transfer assembly to detect an edge of the wafer using a light beam if the wafer laterally shifts as it is transported by the Robotic Transfer Arm during the transferring of the semiconductor wafer from the Photolithography Exposure Scanner to the Coating and Developing Tool.

At processing step S114, The Coating and Developing Tool, developing the latent image to form openings in the photoresist layer.

At processing step S116, Performing further processing of the semiconductor wafer, including but not limited to, Etching material through the openings in the photoresist layer and/or Depositing material in the openings of the photoresist layer.

In the following, some further embodiments are described.

In a nonlimiting illustrative embodiment, a semiconductor wafer processing method is disclosed. The semiconductor wafer processing method comprises: using a coater of a coating and developing tool, coating a semiconductor wafer with a photoresist layer; after the coating, transferring the semiconductor wafer from the coating and developing tool to a photolithography exposure scanner; using the photolithography exposure scanner, forming a latent image of a photomask in the photoresist layer; after the forming, transferring the semiconductor wafer from the photolithography exposure scanner to the coating and developing tool; and using a developer of the coating and developing tool, developing the latent image to form openings in the photoresist layer. The transferring of the semiconductor wafer from the photolithography exposure scanner to the coating and developing tool includes receiving the semiconductor wafer from the photolithography exposure scanner using a wafer transfer assembly mounted to a robotic transfer arm, and using the robotic transfer arm to send the semiconductor wafer from the robotic transfer arm to the coating and developing tool. The wafer transfer assembly includes at least one wafer holder and at least one light interrupt sensor mounted on the wafer transfer assembly, and the receiving includes monitoring for a lateral shift of an edge of the semiconductor wafer using a light beam produced by the light interrupt sensor during the transferring of the semiconductor wafer from the photolithography exposure scanner to the coating and developing tool.

In a nonlimiting illustrative embodiment, a semiconductor wafer processing apparatus is disclosed. The semiconductor wafer processing apparatus comprising: a coating and developing tool including: a coater configured to coat a semiconductor wafer with a photoresist layer, a developer configured to develop a latent image formed in a photoresist layer coating a semiconductor wafer, and a robotic transfer arm configured to transfer a semiconductor wafer from the coating and developing tool to an associated photolithography exposure scanner and to receive a semiconductor wafer from the associated photolithography exposure scanner into the coating and developing tool. The robotic transfer arm includes a wafer transfer assembly mounted to the robotic transfer arm to send the semiconductor wafer from the robotic transfer arm to the coating and developing tool. The wafer transfer assembly includes at least one wafer holder and at least one light interrupt sensor mounted on the wafer transfer assembly to detect an edge of the semiconductor wafer using a light beam if the semiconductor wafer laterally shifts as the semiconductor wafer is transported by the robotic transfer arm during the transferring of the semiconductor wafer from the photolithography exposure scanner to the coating and developing tool.

In a nonlimiting illustrative embodiment, another semiconductor wafer processing apparatus is disclosed. The semiconductor wafer processing apparatus comprising: a coating and developing tool, the coating and developing tool coating the semiconductor wafer with a photoresist layer; and a photolithography exposure scanner, the photolithography exposure scanner configured to form a latent image of a photomask in the photoresist layer. The coating and developing tool includes a robotic transfer arm, the coating and developing tool arranged to transfer a semiconductor wafer from the coating and developing tool to the photolithography exposure scanner and arranged to transfer a semiconductor wafer from the photolithography exposure scanner to the coating and developing tool, and the robotic wafer transfer arm includes a wafer transfer assembly mounted to the robotic transfer arm configured to send the semiconductor wafer from the robotic transfer arm to the coating and developing tool, the wafer transfer assembly including a pincette to support the semiconductor wafer, at least one wafer holder and at least one light interrupt sensor mounted on the wafer transfer assembly to detect an edge of the semiconductor wafer using a light beam if the semiconductor wafer laterally shifts as it is transported by the robotic transfer arm during the transferring of the semiconductor wafer from the coating and developing tool to the photolithography exposure scanner and the transferring of the semiconductor wafer from the photolithography exposure scanner to the coating and developing tool.

In yet further nonlimiting illustrative embodiments, an IRA advance wafer holder is provided, along with system and control methods to detect wafer position and wafer shift associated with an IRA wafer transfer. According to an example embodiment, the IRA advance wafer holder includes the use of left and right light-interrupt or light sensors mounted to left and right wafer holder brackets 151, whereby the wafer holder bracket 151, the wafer holders and the light sensors 156 and 157 travel with the wafer during transfer operations. The function of the light sensors is detecting wafer shift during transfer operations which needs to be addressed by an EE (Equipment Engineer) in the form of pausing the IRA and/or servicing the IRA equipment, or other appropriate actions.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor wafer processing method comprising:
using a coater of a coating and developing tool, coating a semiconductor wafer with a photoresist layer;
after the coating, transferring the semiconductor wafer from the coating and developing tool to a photolithography exposure scanner;
using the photolithography exposure scanner, forming a latent image of a photomask in the photoresist layer;
after the forming, transferring the semiconductor wafer from the photolithography exposure scanner to the coating and developing tool; and
using a developer of the coating and developing tool, developing the latent image to form openings in the photoresist layer;
wherein the transferring of the semiconductor wafer from the photolithography exposure scanner to the coating and developing tool includes:
receiving the semiconductor wafer from the photolithography exposure scanner using a wafer transfer assembly mounted to a robotic transfer arm, and using the robotic transfer arm to send the semiconductor wafer from the robotic transfer arm to the coating and developing tool,
wherein the wafer transfer assembly includes at least one wafer holder and at least one light interrupt sensor mounted on the wafer transfer assembly, and the receiving includes monitoring for a lateral shift of an edge of the semiconductor wafer using a light beam produced by the light interrupt sensor during the transferring of the semiconductor wafer from the photolithography exposure scanner to the coating and developing tool.

2. The semiconductor wafer processing method according to claim 1, wherein the light interrupt sensor is aligned to transmit a light beam orthogonal to a face of the semiconductor wafer.

3. The semiconductor wafer processing method according to claim 1, further comprising:
using a controller operatively connected to the at least one light interrupt sensor, monitoring a state of the light interrupt sensor to determine if the edge of the semiconductor wafer has laterally shifted, and generating an alarm condition if a frequency of shift instances is more than a predetermined value over a predetermined duration of time.

4. The semiconductor wafer processing method according to claim 1, wherein each light interrupt sensor includes a light transmitter and light receiver arranged to detect a light beam emitted by the light transmitter, wherein one of the light transmitter and light receiver is mounted above the semiconductor wafer and the other is mounted below the semiconductor wafer, the method further comprising:
using a controller operatively connected to the light receiver, monitoring an actual light intensity state of the light receiver to determine a wafer shift condition, the wafer shift condition related to the intensity of light received by the light receiver compared to a light intensity first threshold value which is less than an actual light intensity received by the light receiver when the light beam is unobstructed by the semiconductor wafer; and
generating an alarm condition if a frequency of shift instances is more than a predetermined value over a predetermined duration of time.

5. The semiconductor wafer processing method according to claim 4, the method further comprising:
using the controller, monitoring the actual light intensity state of the light receiver to determine a further wafer shift condition, the further wafer shift condition related to the intensity of light received by the light receiver compared to a light intensity second threshold value which is less than an actual light intensity received by the light receiver when the light beam is unobstructed by the semiconductor wafer, and the second threshold value is less than the first threshold value; and
generating an alarm condition if the monitored actual light intensity is less than the second threshold value.

6. The semiconductor wafer processing method according to claim 1, wherein each light interrupt sensor includes a light transmitter and light receiver arranged to detect a light beam emitted by the light transmitter, wherein one of the light transmitter and light receiver is mounted above the semiconductor wafer and the other is mounted below the semiconductor wafer, the method further comprising:
using a controller operatively connected to the light receiver, monitoring an actual light intensity state of the light receiver to determine a wafer shift condition, the wafer shift condition related to the intensity of light received by the light receiver compared to a light intensity threshold value which is less than an actual light intensity received by the light receiver when the light beam is unobstructed by the semiconductor wafer; and
generating an alarm condition if the monitored actual light intensity is less than the threshold value.

7. The semiconductor wafer processing method according to claim 1, further comprising:
using a pincette of the wafer transfer assembly to support the semiconductor wafer and to transfer the semiconductor wafer from the photolithography exposure scanner to the coating and developing tool.

8. The semiconductor wafer processing method according to claim 1, further comprising:
rotating the robotic transfer arm from a position of the photolithography exposure scanner to a position of the coating and developing tool prior to transferring the semiconductor wafer from the photolithography exposure scanner to the coating and developing tool, and using the at least one light interrupt sensor to monitor for a lateral shift of the edge of the semiconductor wafer using the light beam as the robotic transfer arm is rotated.

9. The semiconductor wafer processing method according to claim 1, further comprising:
receiving the semiconductor wafer from the coating and developer tool using the wafer transfer assembly mounted to the robotic transfer arm, and sending the semiconductor wafer from the robotic transfer arm to the photolithography exposure scanner; and
using the at least one light interrupt sensor mounted on the wafer transfer assembly to monitor for a lateral shift of the edge of the semiconductor wafer using the light beam during the transferring of the semiconductor wafer from the photolithography exposure scanner to the coating and developing tool.

10. The semiconductor wafer processing method of claim 1, further comprising:
after the developing, performing at least one semiconductor wafer processing step including at least one of (i) etching material through the openings in the photoresist layer and/or (ii) depositing material in the openings of the photoresist layer.

11. A semiconductor wafer processing apparatus comprising:
a coating and developing tool including:
a coater configured to coat a semiconductor wafer with a photoresist layer,
a developer configured to develop a latent image formed in a photoresist layer coating a semiconductor wafer, and
a robotic transfer arm configured to transfer a semiconductor wafer from the coating and developing tool to an associated photolithography exposure scanner and to receive a semiconductor wafer from the associated photolithography exposure scanner into the coating and developing tool,
wherein the robotic transfer arm includes a wafer transfer assembly mounted to the robotic transfer arm to send the semiconductor wafer from the robotic transfer arm to the coating and developing tool, the wafer transfer assembly including at least one wafer holder and at least one light interrupt sensor mounted on the wafer transfer assembly to detect an edge of the semiconductor wafer using a light beam if the semiconductor wafer laterally shifts as the semiconductor wafer is transported by the robotic transfer arm during the transferring of the semiconductor wafer from the photolithography exposure scanner to the coating and developing tool.

12. The semiconductor wafer processing apparatus according to claim 11, wherein the light interrupt sensor is aligned to transmit the light beam orthogonal to a face of the semiconductor wafer.

13. The semiconductor wafer processing apparatus according to claim 11, further comprising:
a controller operatively connected to the at least one light interrupt sensor, the controller monitoring a state of the light interrupt sensor to determine if the edge of the semiconductor wafer has shifted, and generating an alarm condition if a frequency of shift instances is more than a predetermined value over a predetermined duration of time.

14. The semiconductor wafer processing apparatus according to claim 11, wherein:
the at least one light interrupt sensor includes a light transmitter and light receiver arranged to receive a light beam emitted by the light transmitter, wherein one of the light transmitter and light receiver is mounted above the semiconductor wafer and the other of the light transmitter and light receiver is mounted below the semiconductor wafer; and
the controller is operatively connected to the light receiver and monitors an actual light intensity state of the light receiver to determine a wafer shift condition, the wafer shift condition related to the intensity of light received by the light receiver compared to a light intensity first threshold value which is less than an actual light intensity received by the light receiver when the light beam is unobstructed by the semiconductor wafer, and the controller generating an alarm condition if a frequency of shift instances is more than a predetermined value over a predetermined duration of time.

15. The semiconductor wafer processing apparatus according to claim 14, wherein the wafer shift condition is related to the intensity of light received by the light receiver compared to a light intensity second threshold value which is less than an actual light intensity received by the light receiver when the light beam is unobstructed by the semiconductor wafer, and the second threshold value is less than the first threshold value; and
generating an alarm condition if the monitored actual light intensity is less than the second threshold value.

16. The semiconductor wafer processing apparatus according to claim 11, wherein each light interrupt sensor includes a light transmitter and light receiver arranged to receive a light beam emitted by the light transmitter, wherein one of the light transmitter and light receiver is mounted above the semiconductor wafer and the other of the light transmitter and light receiver is mounted below the semiconductor wafer, and wherein the controller monitors an actual light intensity state of the light receiver to determine a wafer shift condition, the wafer shift condition related to the intensity of light received by the light receiver compared to a light intensity threshold value which is less than an actual light intensity received by the light receiver when the light beam is unobstructed by the semiconductor wafer; and the controller generating an alarm condition if the monitored actual light intensity is less than the threshold value.

17. The semiconductor wafer processing apparatus according to claim 11, wherein:
the wafer transfer assembly includes a pincette to support the semiconductor wafer and to transfer the semiconductor wafer from the photolithography exposure scanner to the coating and developing tool.

18. The semiconductor wafer processing apparatus according to claim 11, wherein the robotic transfer arm is configured to rotate from a position of the photolithography exposure scanner to a position of the coating and developing tool prior to transferring the semiconductor wafer from the photolithography exposure scanner to the coating and developing tool, and the at least one light interrupt sensor detects the edge of the semiconductor wafer using the light beam if the semiconductor wafer laterally shifts as the robotic transfer arm rotates.

19. The semiconductor wafer processing apparatus according to claim 11, wherein the robotic transfer arm is configured to receive the semiconductor wafer from the coating and developer tool using the wafer transfer assembly, and the robotic transfer arm is configured to send the semiconductor wafer from the robotic transfer arm to the photolithography exposure scanner,
wherein the at least one light interrupt sensor mounted on the wafer transfer assembly detects the edge of the semiconductor wafer using the light beam if the semiconductor wafer laterally shifts as it is transported by the robotic transfer arm during the transferring of the semiconductor wafer from the photolithography exposure scanner to the coating and developing tool.

20. A semiconductor wafer processing apparatus comprising:
a coating and developing tool, the coating and developing tool coating the semiconductor wafer with a photoresist layer; and
a photolithography exposure scanner, the photolithography exposure scanner configured to form a latent image of a photomask in the photoresist layer,
wherein the coating and developing tool includes a robotic transfer arm, the coating and developing tool arranged to transfer a semiconductor wafer from the coating and developing tool to the photolithography exposure scanner and arranged to transfer a semiconductor wafer from the photolithography exposure scanner to the coating and developing tool, and the robotic wafer transfer arm includes a wafer transfer assembly mounted to the robotic transfer arm configured to send the semiconductor wafer from the robotic transfer arm to the coating and developing tool, the wafer transfer assembly including a pincette to support the semiconductor wafer, at least one wafer holder and at least one light interrupt sensor mounted on the wafer transfer assembly to detect an edge of the semiconductor wafer using a light beam if the semiconductor wafer laterally shifts as it is transported by the robotic transfer arm during the transferring of the semiconductor wafer from the coating and developing tool to the photolithography exposure scanner and the transferring of the semiconductor wafer from the photolithography exposure scanner to the coating and developing tool.
